(19) United States
(12) Patent Application Publication
(10) Pub. No.: US 2026/0293431 A1
(43) Pub. Date: Sep. 24, 2026

(54) DISPLAY DEVICE AND ELECTRONIC DEVICE

(71) Applicant: Samsung Display Co., Ltd., Yongin-si (KR)

(72) Inventors: Seung Yeon JEONG, Yongin-si (KR); Oh Jeong KWON, Yongin-si (KR); Hyeo Ji KANG, Yongin-si (KR); Tae Ho KIM, Yongin-si (KR); Jong Ho SON, Yongin-si (KR); Hong Yeon LEE, Yongin-si (KR)

(21) Appl. No.: 19/390,023

(22) Filed: Nov. 14, 2025

(30) Foreign Application Priority Data
Mar. 24, 2025 (KR) 10-2025-0037166

(51) Int. Cl. H10K 50/852; G09G 3/3233; H10K 50/125; H10K 50/15; H10K 50/16

(52) U.S. Cl. CPC H10K 50/852; G09G 3/3233; H10K 50/125; H10K 50/156; H10K 50/16; G09G 2300/0426; G09G 2300/0452; G09G 2300/0842; G09G 2320/0242; G09G 2330/021

(57) ABSTRACT

A display device includes: a substrate; and a first light-emitting element in a first emission area, a second light-emitting element in a second emission area, and a third light-emitting element in a third emission area, each of the first, second, and third light-emitting elements including a pixel electrode, a light emitting layer, and a common electrode on the substrate. At least one of the first light-emitting element, the second light-emitting element, or the third light-emitting element further includes an emission pattern between the pixel electrode and the light emitting layer. At least one of the first emission area, the second emission area, or the third emission area in which the emission pattern is located includes a first region where the light emitting layer and the emission pattern do not overlap with each other, and a second region where the light emitting layer and the emission pattern overlap with each other.

### CROSS-REFERENCE TO RELATED APPLICATION

The present application claims priority to and the benefit of Korean Patent Application No. 10-2025-0037166, filed on Mar. 24, 2025, in the Korean Intellectual Property Office, the entire disclosure of which is incorporated by reference herein.

### BACKGROUND

### 1. Field

Aspects of embodiments of the present disclosure relate to a display device and an electronic device.

### 2. Description of the Related Art

As information-oriented society evolves, various demands for display devices are ever increasing. For example, display devices are being employed by a variety of electronic devices, such as smart phones, digital cameras, laptop computers, navigation devices, and smart televisions.

Display devices may be flat panel display devices, such as a liquid-crystal display device, a field emission display device, and a light-emitting display device. Light-emitting display devices include an organic light-emitting display device including an organic light-emitting element, an inorganic light-emitting display device including an inorganic light-emitting element such as an inorganic semiconductor, and a micro-LED display device including ultra-small light-emitting elements.

An organic light-emitting display device includes a display element that includes a light emitting layer made of an organic material between a pixel electrode (e.g., an anode electrode) and a common electrode (e.g., a cathode electrode). Holes provided from the pixel electrode and electrons provided from the common electrode combine with each other in the light emitting layer to form excitons, and then light, for example, such as red, green, or blue light, is generated by using the energy released when the excitons relax from an excited state to the ground state.

The above information disclosed in this Background section is for enhancement of understanding of the background of the present disclosure, and therefore, it may contain information that does not constitute prior art.

### SUMMARY

Pixels, each for emitting red, green, or blue light, may have different emission efficiencies. Accordingly, research is ongoing to optimize the emission efficiencies of the pixels for emitting red, green, or blue light.

Embodiments of the present disclosure may be directed to a high-quality display device and electronic device having improved luminance differences and color differences at different viewing angles.

However, the present disclosure is not limited to the above aspects and features, and the above and additional aspects and features may be set forth, in part, in the description that follows, and in part, may be apparent from the following description.

According to one or more embodiments of the present disclosure, a display device includes: a substrate including a first emission area, a second emission area, and a third emission area; and a first light-emitting element in the first emission area, a second light-emitting element in the second emission area, and a third light-emitting element in the third emission area, each of the first, second, and third light-emitting elements including a pixel electrode, a light emitting layer, and a common electrode on the substrate. At least one of the first light-emitting element, the second light-emitting element, or the third light-emitting element further includes an emission pattern located between the pixel electrode and the light emitting layer. At least one of the first emission area, the second emission area, or the third emission area in which the emission pattern is located includes a first region where the light emitting layer and the emission pattern do not overlap with each other, and a second region where the light emitting layer and the emission pattern overlap with each other.

In an embodiment, the second light-emitting element may include the emission pattern, and an area occupied by the first region in the second emission area may range from 40% to 70%.

In an embodiment, an area occupied by the second region in the second emission area may range from 30% to 60%.

In an embodiment, the emission pattern may include a material configured to emit light of a same color as that of the light emitting layer of the second light-emitting element overlapping with the emission pattern in a thickness direction.

In an embodiment, the third light-emitting element may include the emission pattern, and an area occupied by the first region in the third emission area may range from 20% to 40%.

In an embodiment, an area occupied by the second region in the third emission area may range from 60% to 80%.

In an embodiment, the emission pattern may include a material configured to emit light of a same color as that of the light emitting layer of the third light-emitting element overlapping with the emission pattern in a thickness direction.

In an embodiment, the second light-emitting element and the third light-emitting element may include the emission pattern, and the emission pattern may continuously extend across from the second light-emitting element to the third light-emitting element.

In an embodiment, the display device may further include: a non-emission area located between the second emission area and the third emission area, and the emission pattern may overlap with the non-emission area located between the second emission area and the third emission area, the second emission area, and the third emission area.

In an embodiment, the second emission area may include the first region where the emission pattern and the light emitting layer of the second light-emitting element do not overlap with each other, and the second region where the emission pattern and the light emitting layer of the second light-emitting element overlap with each other. The third emission area may include a third region where the emission pattern and the light emitting layer of the third light-emitting element do not overlap with each other, and a fourth region where the emission pattern and the light emitting layer of the third light-emitting element overlap with each other.

In an embodiment, an area occupied by the first region in the second emission area may range from 40% to 70%, and an area occupied by the third region in the third emission area may range from 20% to 40%.

In an embodiment, the first emission area may be configured to output blue light, the second emission area may be configured to output green light, and the third emission area may be configured to output red light.

According to one or more embodiments of the present disclosure, a display device includes: a substrate including a first emission area and a second emission area; a first pixel electrode in the first emission area, and a second pixel electrode in the second emission area; an emission pattern continuously extending across the first pixel electrode and the second pixel electrode; a first light emitting layer overlapping with the first pixel electrode and the emission pattern, and a second light emitting layer overlapping with the second pixel electrode and the emission pattern; and a common electrode on the first light emitting layer and the second light emitting layer. The first emission area includes a first region where the first light emitting layer and the emission pattern do not overlap with each other, and a second region where the first light emitting layer and the emission pattern overlap with each other. The second emission area includes a third region where the second light emitting layer and the emission pattern do not overlap with each other, and a fourth region where the second light emitting layer and the emission pattern overlap with each other. The second region and the fourth region are adjacent to each other.

In an embodiment, an area occupied by the first region in the first emission area may range from 40% to 70%, and an area occupied by the third region in the second emission area may range from 20% to 40%.

In an embodiment, an area occupied by the second region in the first emission area may range from 30% to 60%, and an area occupied by the fourth region in the second emission area may range from 60% to 80%.

In an embodiment, the display device may further include: a hole functional layer between the first pixel electrode and the emission pattern, and between the second pixel electrode and the emission pattern; and an electron functional layer between the first light emitting layer and the common electrode, and between the second light emitting layer and the common electrode. The hole functional layer and the electron functional layer may be common layers continuously extending across the first emission area and the second emission area.

In an embodiment, the display device may further include: a first hole functional layer on the second pixel electrode; a second hole functional layer on the first hole functional layer; and an auxiliary light emitting layer on the second hole functional layer and the first hole functional layer. The emission pattern may be located between the first hole functional layer and the second hole functional layer, and the second light emitting layer may be located on the auxiliary light emitting layer.

In an embodiment, the substrate may further include a third emission area. The display device may further include: a third pixel electrode in the third emission area; a third light emitting layer on the third pixel electrode; and the common electrode on the third light emitting layer. The emission pattern may not overlap with the third emission area.

In an embodiment, the first light emitting layer may be configured to emit green light, the second light emitting layer may be configured to emit red light, and the third light emitting layer may be configured to emit blue light.

According to one or more embodiments of the present disclosure, an electronic device includes: a display device configured to display images; a processor configured to provide an image data signal to the display device; a memory configured to store data information for an operation; and a power circuit configured to generate power. The display device includes: a substrate including a first emission area, a second emission area, and a third emission area; and a first light-emitting element in the first emission area, a second light-emitting element in the second emission area, and a third light-emitting element in the third emission area, each of the first, second, and third light-emitting elements including a pixel electrode, a light emitting layer, and a common electrode on the substrate. At least one of the first light-emitting element, the second light-emitting element, or the third light-emitting element further includes an emission pattern located between the pixel electrode and the light emitting layer. At least one of the first emission area, the second emission area, or the third emission area in which the emission pattern is located includes a first region where the light emitting layer and the emission pattern do not overlap with each other, and a second region where the light emitting layer and the emission pattern overlap with each other.

According to some embodiments of the present disclosure, it may be possible to improve luminance differences and color differences relative to the front of a display device by forming different resonance characteristics in an emission area using an emission pattern. Accordingly, a display device and an electronic device including the display device according to some embodiments may achieve high-quality display characteristics.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram of an electronic device according to an embodiment of the present disclosure.

FIG. 2 illustrates some electronic devices according to some embodiments of the present disclosure.

FIG. 3 is a plan view of a display device according to an embodiment of the present disclosure.

FIG. 4 is a schematic view showing a layout of a circuitry of a substrate of a display device according to an embodiment.

FIG. 5 is an equivalent circuit diagram of a pixel of a display device according to an embodiment of the present disclosure.

FIG. 6 is a plan view showing emission areas of a display device according to an embodiment of the present disclosure.

FIG. 7 is a cross-sectional view taken along the line Q1-Q1′ of FIG. 6.

FIG. 8 is a cross-sectional view showing paths of light generated in an emission emitting stack.

FIG. 9 is a plan view showing emission areas of a display device according to an embodiment of the present disclosure.

FIG. 10 is a cross-sectional view showing light-emitting elements of a display device according to an embodiment of the present disclosure.

FIG. 11 is a graph showing a luminance improvement rate at a 60-degree viewing angle relative to a front versus a ratio of an area of a first region to a second emission area.

FIG. 12 is a graph showing differences in a luminance improvement rate at a 60-degree viewing angle relative to a front versus a ratio of an area of a first region to a second emission area.

FIG. 13 is a graph showing a luminance ratio versus a viewing angle.

FIG. 14 is a graph showing differences in a luminance ratio versus a viewing angle.

FIG. 15 is a cross-sectional view showing emission areas of a display device according to an embodiment of the present disclosure.

FIG. 16 is a plan view showing emission areas of a display device according to an embodiment of the present disclosure.

FIG. 17 is a graph showing a luminance improvement rate at a 60-degree viewing angle relative to a front versus a ratio of an area of a first region to a third emission area.

FIG. 18 is a graph showing differences in a luminance improvement rate at a 60-degree viewing angle relative to a front versus a ratio of an area of a first region to a third emission area.

FIG. 19 is a graph showing a luminance ratio versus a viewing angle.

FIG. 20 is a graph showing differences in a luminance ratio versus a viewing angle.

FIG. 21 is a cross-sectional view showing emission areas of a display device according to an embodiment of the present disclosure.

FIG. 22 is a cross-sectional view showing light-emitting elements of a display device according to an embodiment of the present disclosure.

FIG. 23 is a plan view showing emission areas of a display device according to an embodiment of the present disclosure.

FIG. 24 is a graph showing a luminance improvement rate at a 60-degree viewing angle relative to a front versus a ratio of an area of a first region to a second emission area and a ratio of an area of a third region to a third emission area.

FIG. 25 is a graph showing differences in a luminance improvement rate at a 60-degree viewing angle relative to a front versus a ratio of an area of a first region to a second emission area and a ratio of an area of a third region to a third emission area.

FIG. 26 is a graph showing a luminance improvement rate at a 60-degree viewing angle relative to a front versus a ratio of an area of a first region to a second emission area.

FIG. 27 is a graph showing differences in a luminance improvement rate at a 60-degree viewing angle relative to a front versus a ratio of an area of a first region to a second emission area.

FIG. 28 is a graph showing a front efficiency versus a ratio of an area of a first region in a second emission area.

FIG. 29 is a graph showing differences in white color coordinates versus a viewing angle.

FIG. 30 is a graph showing a luminance versus a viewing angle.

FIG. 31 is a graph showing differences in a luminance ratio versus a viewing angle.

FIGS. 32 and 33 are plan views showing emission areas of a display device according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The display device according to embodiments described in more detail hereinafter may be applied to a variety of suitable electronic devices. An electronic device according to some embodiments includes the display device described in more detail hereinafter, and may further include a module or a device having additional features in addition to the display device.

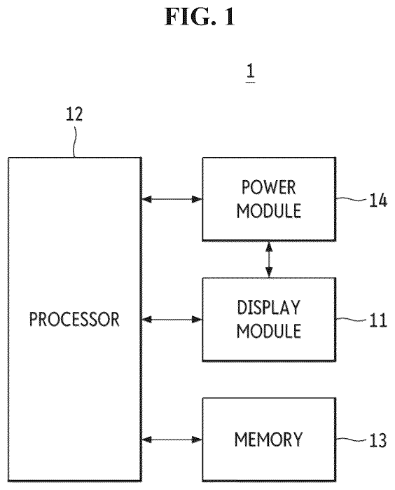

FIG. 1 is a block diagram of an electronic device according to an embodiment of the present disclosure.

Referring to FIG. 1, an electronic device 1 according to an embodiment of the present disclosure may include a display module (e.g., a display or a touch-display) 11, a processor 12, a memory 13, and a power module (e.g., a power circuit or a power supply circuit) 14.

The processor 12 may include at least one of a central processing unit (CPU), an application processor (AP), a graphic processing unit (GPU), a communication processor (CP), an image signal processor (ISP), and/or a controller.

The memory 15 may store data information used for the operation of the processor 12 or the display module 11. When the processor 12 executes an application stored in the memory 15, an image data signal and/or an input control signal may be transmitted to the display module 11. The display module 11 may process the received signal, and may output image information through a display screen.

The power module 14 may include a power supply module, such as a power adapter and a battery device, and a power conversion module that converts the power supplied by the power supply module to generate power used for the operation of the electronic device 10.

At least one of the elements of the electronic device 1 described above may be included in the display device according to some embodiments. In addition, some of the individual modules functioning as a single module may be included in the display device, while some others may be provided separately from the display device. For example, the display device may include the display module 11, and the processor 12, the memory 13 and the power module 14 may be implemented as other devices inside the electronic device 1 instead of the display device.

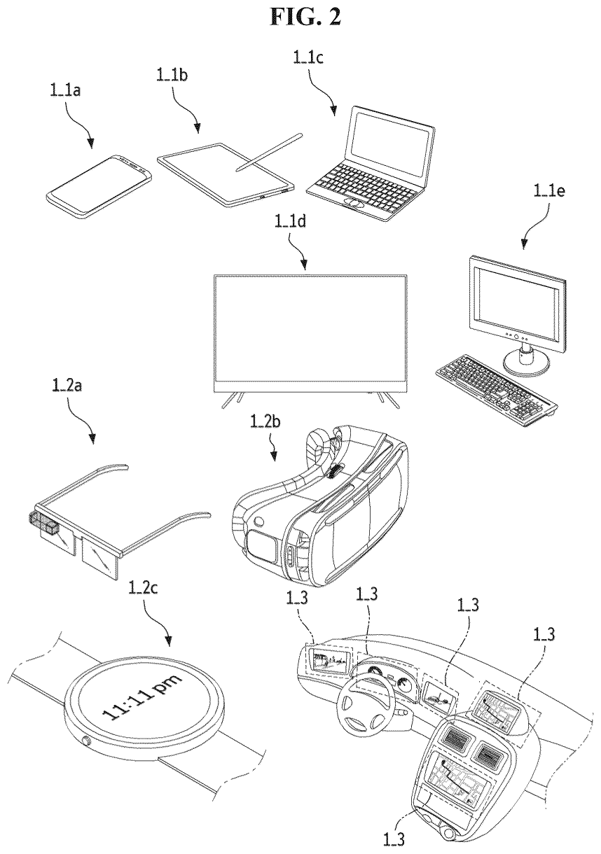

FIG. 2 illustrates some electronic devices according to some embodiments of the present disclosure.

Referring to FIG. 2, a variety of electronic devices employing display devices according to some embodiments may include not only image display electronic devices, such as a smart phone 1_1a, a tablet PC 1_1b, a laptop computer 1_1c, a TV 1_1d, and a desktop monitor 1_1e, but may also include wearable electronic devices including display modules, such as smart glasses 1_2a, a head-mounted display 1_2b and a smart watch 1_2c, and electronic devices for vehicles 1_3 including display modules, such as a center information display (CID) placed on a dashboard, a center fascia, and a room mirror display.

As used herein, the terms “above,” “top,” and “upper surface” refer to the upper side of a display device 10 (e.g., the side indicated by the arrow in the third direction DR3), whereas the terms “below,” “bottom,” and “lower surface” refer to the lower side of the display device 10 (e.g., the opposite side in the third direction DR3). As used herein, the terms “left,” “right,” “upper,” and “lower” sides indicate relative positions when the display device 10 is viewed from the top (e.g., in a plan view). For example, the “left side” refers to the opposite of the first direction DR1, the “right side” refers to the side indicated by the arrow of the first direction DR1, the “upper side” refers to the side indicated by the arrow of the second direction DR2, and the “lower side” refers to the opposite of the second direction DR2.

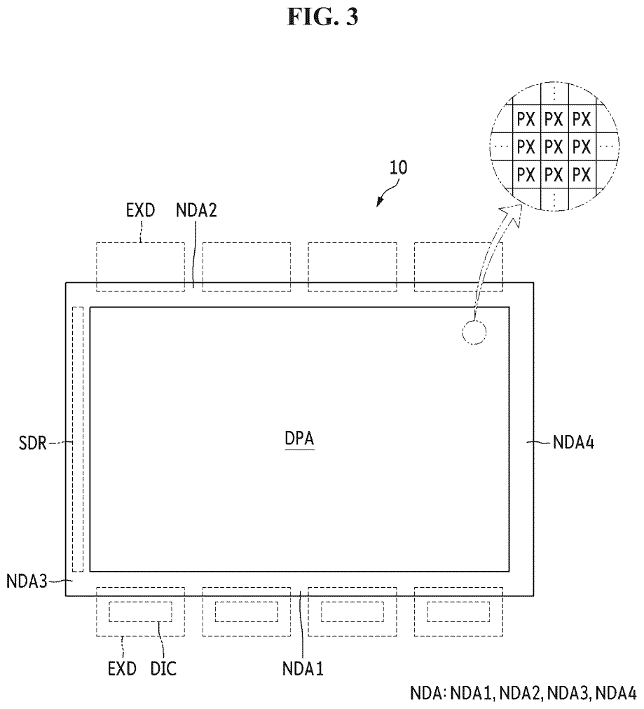

FIG. 3 is a plan view of a display device according to an embodiment of the present disclosure.

Referring to FIG. 3, a display device 10 according to an embodiment of the present disclosure may be applied to a smart phone, a mobile phone, a tablet PC, a personal digital assistant (PDA), a portable multimedia player (PMP), a television set, a game machine, a wristwatch-kind of electronic device, a head-mounted display, a personal computer monitor, a laptop computer, a car navigation system, a car instrument cluster, a digital camera, a camcorder, an outdoor billboard, an electronic billboard, various suitable medical apparatuses, various suitable home appliances, such as a refrigerator and a laundry machine, Internet of things (IoT) devices, and the like. Hereinafter, for convenience of illustration, a television may be described in more detail as an example of the display device 10. The television (TV) may have a high resolution or a ultra high resolution, such as HD, UHD, 4K, and 8K.

In addition, the display device 10 according to some embodiments may be variously classified by the way in which images are displayed. Examples of the classification of the display devices may include an organic light-emitting display device (OLED), an inorganic light-emitting display device (inorganic EL), a quantum-dot light-emitting display device (QED), a micro LED display device (micro-LED), a nano LED display device (nano-LED), a plasma display device (PDP), a field emission display device (FED), a cathode ray display device (CRT), a liquid-crystal display device (LCD), an electrophoretic display device (EPD), and the like. Hereinafter, for convenience of illustration, an organic light-emitting display device may be described in more detail as an example of the display device, and the organic light-emitting display device may be simply referred to as a display device unless otherwise necessary to discern it from others. However, the present disclosure is not limited to the organic light-emitting display device, and any one of the above-listed display devices or any other display device known to those having ordinary skill in the art may be applicable.

According to the embodiment, the display device 10 may have a square shape or a rectangular shape when viewed from the top (e.g., in a plan view). When the display device 10 is a television, it may be oriented such that the longer sides thereof are positioned in a horizontal direction. However, the present disclosure is not limited thereto. The longer sides may be positioned in a vertical direction. As another example, the display device 10 may be installed rotatably so that the longer sides are positioned in the horizontal direction or the vertical direction as needed or desired.

The display device 10 may include a display area DPA and a non-display area NDA. The display area DPA may be an active area where images are displayed. The display area DPA may have, but is not limited to, a rectangular shape similar to that of the general shape of the display device 10 when viewed from the top (e.g., in a plan view).

The display area DPA may include a plurality of pixels PX. The plurality of pixels PX may be arranged in a matrix. The shape of each of the pixels PX may be, but is not limited to, a rectangle or a square when viewed from the top (e.g., in a plan view). Each of the pixels PX may have a diamond shape having sides that are inclined with respect to a side of the display device 10. The plurality of pixels PX may include different color pixels PX. For example, the pixels PX may include, but is not limited to, a red pixel, a green pixel, and a blue pixel. The color pixels PX may be arranged alternately in a RGB stripe pattern or an RGBG matrix (e.g., a PENTILE® matrix, PENTILE® being a duly registered trademark of Samsung Display Co., Ltd.).

The non-display area NDA may be disposed around the display area DPA. The non-display area NDA may surround (e.g., around a periphery of) the display area DPA entirely or partially. The display area DPA may have a rectangular shape, and the non-display area NDA may be disposed to be adjacent to four sides of the display area DPA. The non-display area NDA may form a bezel of the display device 10.

In the non-display areas NDA, a driver circuit or a driving element for driving the display area DPA may be arranged. According to an embodiment of the present disclosure, a pad area may be located on a display substrate of the display device 10 in a first non-display area NDA1 disposed adjacent to a first longer side (e.g., the lower side in FIG. 3) of the display device 10 and a second non-display area NDA2 adjacent to a second longer side (e.g., the upper side in FIG. 3) of the display device 10. An external device EXD may be mounted on a pad electrode of the pad area. Examples of the external device EXD may include a connection film, a printed circuit board, a driver chip DIC, a connector, a line connection film, and the like. A scan driver SDR formed directly on the display substrate of the display device 10 may be located in a third non-display area NDA3 disposed adjacent to a first shorter side of the display device 10 (e.g., the left side in FIG. 3). The scan driver SDR may be located in a fourth non-display area NDA4 on a second shorter side (e.g., the right side in FIG. 3) of the display device 10.

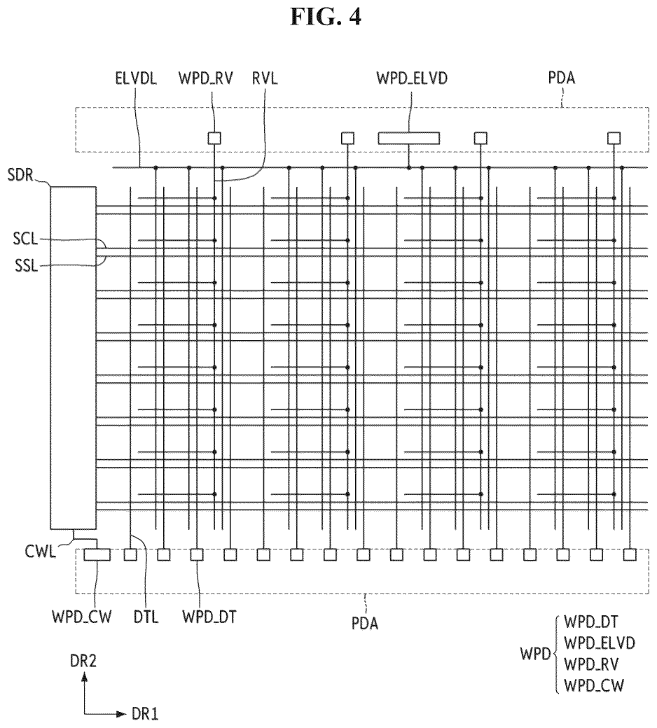

FIG. 4 is a schematic view showing a layout of a circuitry of a substrate of a display device according to an embodiment.

Referring to FIG. 4 in conjunction with FIG. 3, a plurality of lines may be arranged on a substrate. The plurality of lines may include a scan line SCL, a sensing signal line SSL, a data line DTL, a reference voltage line RVL, a first supply voltage line ELVDL, and the like.

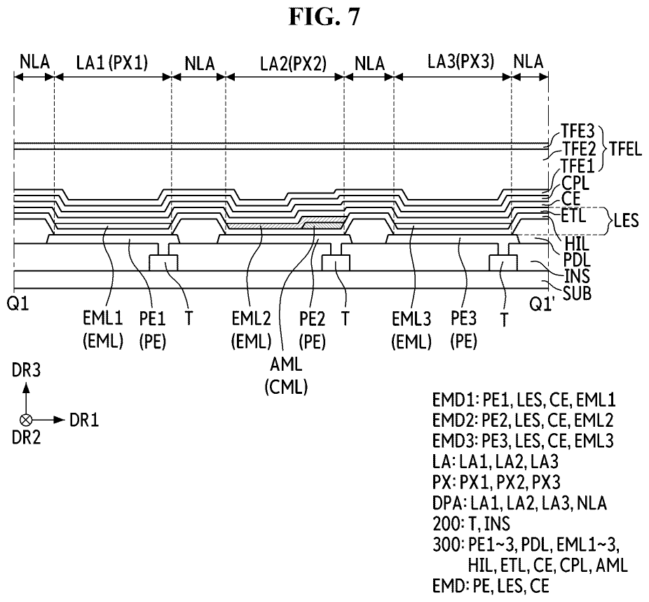

The scan line SCL and the sensing signal line SSL may be extended in the first direction DR1. The scan line SCL and the sensing signal line SSL may be connected to the scan driver SDR. The scan driver SDR may include a driver circuit formed of a circuit layer (e.g., see 200 in FIG. 7). The scan driver SDR may be disposed in the third non-display area NDA3 on the substrate, but the present disclosure is not limited thereto. The scan driver SDR may be disposed in the fourth non-display area NDA4, or in both the third non-display area NDA3 and the fourth non-display area NDA4. The scan driver SDR may be connected to a signal connection line CWL. At least one end of the signal connection line CWL may form a pad WPD_CW on the first non-display area NDA1 and/or the second non-display area NDA2, and may be connected to an external device EXD (e.g., see FIG. 1).

The data line DTL and the reference voltage line RVL may be extended in the second direction DR2 crossing the first direction DR1. A first supply voltage line ELVDL may include a portion extending in the second direction DR2. The first supply voltage line ELVDL may further include a portion extending in the first direction DR1. The first supply voltage line ELVDL may have, but is not limited to, a mesh structure.

The wire pads WPD may be disposed at at least one end of the data line DTL, the reference voltage line RVL, and the first supply voltage line ELVDL. The wire pads WPD may be disposed in the pad area PDA of the non-display area NDA. According to an embodiment of the present disclosure, a wire pad WPD_DT of the data line DTL (hereinafter, referred to as a data pad) may be disposed in the pad area PDA of the first non-display area NDA1. A wire pad WPD_RV of the reference voltage line RVL (hereinafter referred to as a reference voltage pad) and a wire pad WPD_ELVD of the first supply voltage line ELVDL (hereinafter referred to as a first supply voltage pad) may be disposed in the pad area PDA of the second non-display area NDA2. As another example, the data pad WPD_DT, the reference voltage pad WPD_RV, and the first supply voltage pad WPD_ELVD may all be disposed in the same area as each other (e.g., in the first non-display area NDA1). As described above, the external devices EXD (e.g., see FIG. 3) may be mounted on the wire pad WPD. The external devices EXD may be mounted on the wire pads WPD by an anisotropic conductive film, ultrasonic bonding, and/or the like.

Each of the pixels PX on the substrate includes a pixel driver circuit. The lines may pass through the pixels PX or the periphery thereof to apply a driving signal to the pixel driver circuit. The pixel driver circuit may include transistors and a capacitor. The numbers of transistors and capacitors of each pixel driver circuit may be variously modified as needed or desired. Hereinafter, the pixel driver circuit having a 3T1C structure (e.g., a three transistor and one capacitor structure) including three transistors and one capacitor will be described as an example. However, the present disclosure is not limited thereto. A variety of modified pixel structure may be employed, such as a 2T1C structure (e.g., a two transistor and one capacitor structure), a 7T1C structure (e.g., a seven transistor and one capacitor structure), or a 6T1C structure (e.g., a six transistor and one capacitor structure).

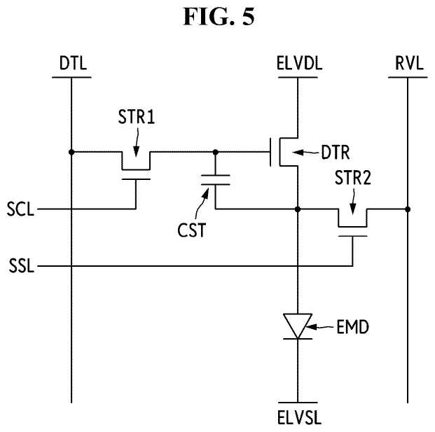

FIG. 5 is an equivalent circuit diagram of a pixel of a display device according to an embodiment of the present disclosure.

Referring to FIG. 5, each of the pixels PX of the display device according to the embodiment includes three transistors DTR, STR1, and STR2, and one capacitor CST for storage, in addition to a light-emitting diode EMD.

The light-emitting diode EMD emits light in proportion to a current supplied through the driving transistor DTR. The light-emitting diode EMD may be implemented as an organic light-emitting diode, a micro light-emitting diode, a nano light-emitting diode, or the like.

The first electrode (e.g., the anode electrode) of the light-emitting diode EMD may be connected to the source electrode of the driving transistor DTR, and the second electrode (e.g., the cathode electrode) of the light-emitting diode EMD may be connected to a second supply voltage line ELVSL from which a low-level voltage (e.g., a second supply voltage) is applied, which may be lower than a high-level voltage (e.g., a first supply voltage) of a first supply voltage line ELVDL.

The driving transistor DTR adjusts a current flowing from the first supply voltage line ELVDL from which the first supply voltage is applied to the light-emitting diode EMD according to a voltage difference between the gate electrode and the source electrode. The gate electrode of the driving transistor DTR may be connected to a source/drain electrode of the first switching transistor STR1, the source electrode may be connected to the first electrode of the light-emitting diode EMD, and the drain electrode may be connected to the first supply voltage line ELVDL from which the first supply voltage is applied.

The first switching transistor STR1 is turned on by a scan signal of a scan line SCL to connect a data line DTL with the gate electrode of the driving transistor DTR. A gate electrode of the first switching transistor STR1 may be connected to the scan line SCL, the first source/drain electrode may be connected to the gate electrode of the driving transistor DTR1, and a second source/drain electrode thereof may be connected to the data line DTL.

The second switching transistor STR2 may be turned on by a sensing signal of a sensing signal line SSL to connect a reference voltage line RVL to the source electrode of the driving transistor DTR. A gate electrode of the second switching transistor STR2 may be connected to the sensing signal line SSL, the first source/drain electrode thereof may be connected to the reference voltage line RVL, and the second source/drain electrode thereof may be connected to the source electrode of the driving transistor DTR.

According to an embodiment of the present disclosure, the first source/drain electrode of each of the first and second switching transistors STR1 and STR2 may be a source electrode, while the second source/drain electrode thereof may be a drain electrode. However, the present disclosure is not limited thereto. The first source/drain electrode of each of the first and second switching transistors STR1 and STR2 may be a drain electrode, while the second source/drain electrode thereof may be a source electrode.

The capacitor CST may be formed between the gate electrode and the source electrode of the driving transistor DTR. The storage capacitor CST stores a voltage difference between the gate voltage and the source voltage of the driving transistor DTR.

The driving transistor DTR and the first and second switching transistors STR1 and STR2 may be formed as thin-film transistors. In addition, although FIG. 3 shows that each of the driving transistor DTR and the first and second switching transistors STR1 and STR2 is implemented as an n-type MOSFET (metal oxide semiconductor field effect transistor), the present disclosure is not limited thereto. For example, the driving transistor DTR and the first and second switching transistors STR1 and STR2 may be implemented as p-type MOSFETs, or some of them may be implemented as n-type MOSFETs while others may be implemented as p-type MOSFETs.

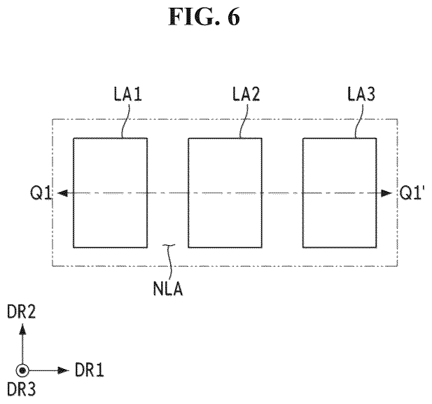

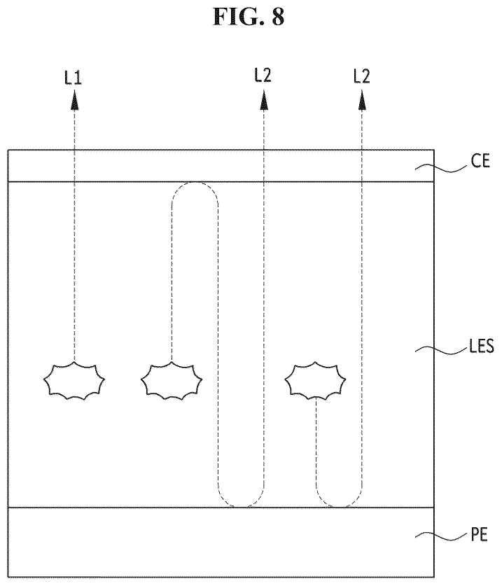

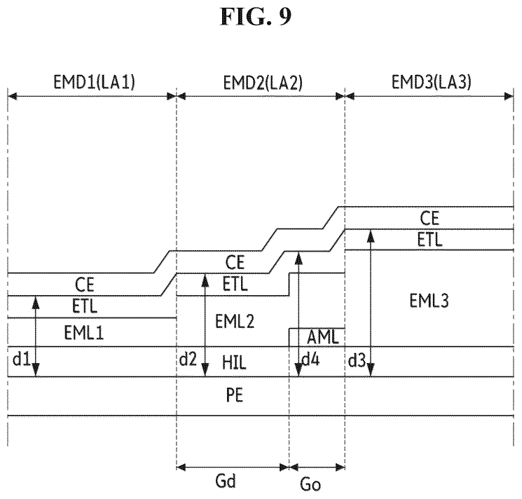

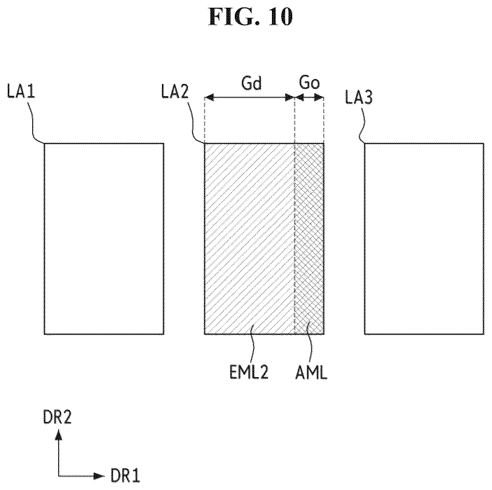

FIG. 6 is a plan view showing emission areas of a display device according to an embodiment of the present disclosure. FIG. 7 is a cross-sectional view taken along the line Q1-Q1′ of FIG. 6. FIG. 8 is a cross-sectional view showing paths of light generated in an emission emitting stack. FIG. 9 is a plan view showing emission areas of a display device according to an embodiment of the present disclosure. FIG. 10 is a cross-sectional view showing light-emitting elements of a display device according to an embodiment of the present disclosure.

Referring to FIG. 6, a plurality of emission areas LA1, LA2, and LA3, and a non-emission area NLA may be defined on the substrate in the display area DPA. In some embodiments, the plurality of emission areas LA1, LA2, and LA3 in the display area DPA may include a first emission area LA1, a second emission area LA2, and a third emission area LA3. In the first, second, and third emission areas LA1, LA2, and LA3, light generated in the light-emitting elements of the substrate exits to the outside. In the non-emission area NLA, no light exits to the outside.

In some embodiments, different colored light may exit out of the first emission area LA1, the second emission area LA2, and the third emission area LA3, respectively. For example, the first emission area LA1 may emit light of a first color, the second emission area LA2 may emit light of a second color, and the third emission area LA3 may emit light of a third color. The light of the first color may be blue light having a peak wavelength in the range of approximately 440 to 480 nm. The light of the second color may be green light having a peak wavelength in the range of approximately 510 to 550 nm. The light of the third color may be red light having a peak wavelength in the range of approximately 610 to 650 nm. However, the present disclosure is not limited thereto. The light of the second color may be red light, and the light of the third color may be green light.

In some embodiments, the first emission area LA1, the second emission area LA2, and the third emission area LA3 may form a single group, and a plurality of single groups may be defined in the display area DPA.

In some embodiments, as shown in FIG. 6, the first emission area LA1, the second emission area LA2, and the third emission area LA3 may be arranged sequentially along a direction. In some embodiments, the first emission area LA1, the second emission area LA2, and the third emission area LA3 may form a single group, and such groups may be repeatedly arranged in the display area DPA. However, the present disclosure is not limited thereto. The arrangement of the first emission areas LA1, the second emission areas LA2, and the third emission areas LA3 may be arranged in various suitable ways.

Referring to FIG. 7, the display device 10 may include a substrate SUB, a circuit layer 200 arranged on the substrate SUB, a light-emitting element layer 300 arranged on the circuit layer 200, and a thin-film encapsulation layer TFEL arranged on the light-emitting element layer 300.

The substrate SUB may be an insulating substrate. The substrate SUB may be made of an insulating material, such as glass, quartz, and/or a polymer resin. The substrate SUB may be either a rigid substrate, or a flexible substrate that may be bent, folded, or rolled.

The display area DPA may be defined on the substrate SUB. In the display area DPA, emission areas LA1, LA2, and LA3 of the pixels PX, and a non-emission area NLA around the emission areas LA1, LA2, and LA3 may be defined. According to an embodiment of the present disclosure, the display area DPA may include a first emission area LA1 of a first pixel PX1, a second emission area LA2 of a second pixel PX2, a third emission area LA3 of a third pixel PX3, and a non-emission area NLA surrounding (e.g., around peripheries of) the first emission area LA1, the second emission area LA2, and the third emission area LA3.

The circuit layer 200 may be optionally arranged or provided on the substrate SUB. The circuit layer 200 may include circuit elements, such as transistors T, lines, and the like. In FIG. 7, as an example of the circuit elements provided in the circuit layer 200, the transistors T connected to the light-emitting elements EMD of the pixels PX1, PX2, and PX3 are schematically depicted. According to an embodiment of the present disclosure, each of the transistors T may be a thin-film transistor including polysilicon, or a thin-film transistor including an oxide semiconductor.

An insulating layer INS may be arranged over the circuit elements, such as the transistors T and the lines. According to an embodiment of the present disclosure, the insulating layer INS may be a planarization layer including an organic film. For example, the insulating layer INS may include an acrylic resin, an epoxy resin, an imide resin, an ester resin, and/or the like.

The light-emitting element layer 300 including the light-emitting elements EMD may be placed on the circuit layer 200. The light-emitting elements EMD may be located in the emission areas LA1, LA2, and LA3, respectively, and each of the emission areas LA1, LA2, and LA3 may include at least one light-emitting element EMD. For example, a first light-emitting element EMD1 may be placed in the first emission area LA1, a second light-emitting element EMD2 may be placed in the second emission area LA2, and a third light-emitting element EMD3 may be placed in the third emission area LA3. According to an embodiment of the present disclosure, the light-emitting elements EMD may be formed directly on a surface of the substrate SUB on which the circuit layer 200 is formed.

Each of the light-emitting elements EMD may include a pixel electrode PE (also referred to as an anode electrode or a first electrode), an emission stack LES (also referred to as a light-emitting stack or a light-emitting unit), and a common electrode CE (also referred to as a cathode electrode or a second electrode). Each of the light-emitting elements EMD may penetrate the insulating layer INS of the circuit layer 200, and may be connected to at least one circuit element (e.g., a transistor T) forming the pixel circuit of that pixel PX.

According to an embodiment of the present disclosure, the pixel electrode PE, the emission stack LES, and the common electrode CE may be sequentially arranged on the insulating layer INS of the circuit layer 200. The pixel electrode PE and the common electrode CE may face each other, and the emission stack LES may be interposed between the pixel electrode PE and the common electrode CE.

One of the pixel electrode PE or the common electrode CE may be an anode electrode, while the other one may be a cathode electrode. For example, the pixel electrode PE may be an anode electrode, and the common electrode CE may be a cathode electrode.

The pixel electrodes PE may be separate electrodes individually located and/or formed in the respective pixels PX and/or the respective emission areas LA. For example, the first light-emitting element EMD1 may include a first pixel electrode PE1 located in the first emission area LA1, the second light-emitting element EMD2 may include a second pixel electrode PE2 located in the second emission area LA2, and the third light-emitting element EMD3 may include a third pixel electrode PE3 located in the third emission area LA3. The first pixel electrode PE1, the second pixel electrode PE2, and the third pixel electrode PE3 may be spaced apart from one another.

According to an embodiment of the present disclosure, a portion of the emission stack LES and the common electrode CE may be common layers which are formed commonly and/or continuously across the pixels PX and/or the emission areas LA and shared by the light-emitting elements EMD. For example, a hole functional layer HIL and an electron functional layer ETL of the emission stack LES and the common electrode CE may be arranged or formed over the entire display area DA, and each of the light-emitting elements ED may include parts of the emission stack LES and the common electrode CE. For example, the hole function layer HIL and the electron function layer ETL of the emission stack LES and the common electrode CE may be arranged on the pixel electrodes PE of the light-emitting elements EMD, and may be formed continuously over the entire display area DPA.

According to an embodiment of the present disclosure, the pixel electrode PE may be a reflective electrode including a reflective layer, and the common electrode CE may be a translucent electrode. According to an embodiment of the present disclosure, the pixel electrode PE may include a reflective layer, and a transparent conductive layer located on the reflective layer. According to an embodiment of the present disclosure, the reflective layer may be a metal layer containing silver (Ag), magnesium (Mg), aluminum (Al), platinum (Pt), palladium (Pd), gold (Au), nickel (Ni), neodymium (Nd), iridium (Ir), chrome (Cr), or a suitable compound thereof. According to an embodiment of the present disclosure, the transparent conductive layer may include a transparent conductive oxide (TCO). For example, the transparent conductive layer may include at least one material selected from the group consisting of indium tin oxide (ITO), indium zinc oxide (IZO), indium gallium oxide (IGO), aluminum zinc oxide (AZO), zinc oxide (ZnO), indium oxide (In₂O₃), indium tin zinc oxide (ITZO), tungsten oxide (WOx), titanium oxide (TiO₂), and magnesium oxide (MgO), or other suitable transparent conductive materials. For example, the pixel electrode PE may have a double-layered structure, such as ITO/Ag, Ag/ITO, ITO/Mg, and ITO/MgF, or a triple-layered structure such as ITO/Ag/ITO.

A pixel-defining layer (e.g., a bank) PDL may be arranged between the pixel electrodes PE. The pixel-defining layer PDL may define the emission areas LA and the non-emission area NLA. The pixel-defining layer PDL may be located in the non-emission area NLA, and may include openings in the emission areas LA to expose the pixel electrodes PE, respectively. For example, the pixel-defining layer PDL may surround (e.g., around peripheries of) the emission areas LA, and at least a portion of the pixel-defining layer PDL may be located between the emission areas LA. According to an embodiment of the present disclosure, the pixel-defining layer PDL may be in a mesh pattern including the openings that expose the emission areas LA of the pixels PX.

According to an embodiment of the present disclosure, the pixel-defining layer PDL may overlap with parts of the pixel electrodes PE. For example, the pixel-defining layer PDL may overlap with the edges of the pixel electrodes PE that are extended to the non-emission area NLA.

The emission stack LES including at least one emissive layer may be located on the pixel electrodes PE and the pixel-defining layer PDL. According to an embodiment of the present disclosure, at least a portion of the emission stack LES may be a common layer that is formed continuously across the emission areas LA and the non-emission area NLA.

According to an embodiment of the present disclosure, the emission stack ST may include a high-molecular weight organic material or a low-molecular weight organic material that emits light of a desired color. In addition to a variety of organic materials, the emission stack LES may further include metal-containing compounds such as organometallic compounds, inorganic materials such as quantum dots, and/or the like. The emission stack LES may include at least one emissive layer. For example, the first light-emitting element EMD1 may include a first light emitting layer EML1 that emits light of the first color, the second light-emitting element EMD2 may include a second light emitting layer EML2 that emits light of the second color, and the third light-emitting element EMD3 may include a third light emitting layer EML3 that emits light of the third color.

Each emissive layer may include a host and a dopant. The light emitting layer may be formed by using a phosphorescent or fluorescent material as the dopant in a host material. The material of the host is not particularly limited, as long as it may be suitably used, and may include Alq3(tris(8-hydroxyquinolino)aluminum), CBP(4,4′-bis(N-carbazolyl)-1,1′-biphenyl), PVK(poly(n-vinylcabazole)), ADN(9,10-di(naphthalene-2-yl)anthracene), TCTA(4,4′,4″-Tris(carbazol-9-yl)-triphenylamine), TPBi(1,3,5-tris(N-phenylbenzimidazole-2-yl)benzene), TBADN(3-tert-butyl-9,10-di(naphth-2-yl)anthracene), DSA(distyrylarylene), CDBP(4,4′-bis(9-carbazolyl)-2,2″-dimethyl-biphenyl), MADN(2-Methyl-9,10-bis(naphthalen-2-yl)anthracene), and/or the like. The colors of light emitted from the light emitting layer may be determined by a combination of the host material and the dopant material.

According to an embodiment of the present disclosure, the first light emitting layer EML1 of the first light-emitting element EMD1 may be a blue emissive layer that emits blue light, and may include a fluorescent material including one selected from the group consisting of spiro-DPVBi, spiro-6P, DSB(distyryl-benzene), DSA(distyrylarylene), PFO(polyfluorene) polymer, and PPV (poly(p-phenylene vinylene) polymer. The dopant material contained in the blue emissive layer may be, for example, a metal complex such as (4,6-F2ppy)2Irpic, or an organometallic complex. As another example, the blue emissive layer may include a phosphorescent material including an organometallic complex such as (4,6-F2ppy)2Irpic.

According to an embodiment of the present disclosure, the second light emitting layer EML2 of the second light-emitting element EMD2 may be a green emissive layer that emits green light, and may include a fluorescent material containing Alq3(tris(8-hydroxyquinolino)aluminum). The dopant material contained in the green emissive layer may be, for example, a metal complex such as Ir(ppy)3(fac-tris(2-phenylpyridine)iridium), or an organometallic complex.

According to an embodiment of the present disclosure, the third light emitting layer EML3 of the third light-emitting element EMD3 may be a red emissive layer that emits red light, and may include a fluorescent material including PBD:Eu(DBM)3(Phen) (tris(dibenzoylmethanato)phenanthoroline europium), or perylene. The dopant material contained in the red emissive layer may be, for example, metal complexes, such as PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), and/or PtOEP(octaethylporphyrin platinum, or an organometallic complex.

The emission stack LES may further include at least one intermediate layer overlapping with at least one emissive layer. For example, the emission stack LES may include a hole functional layer HIL between the pixel electrode PE and the light emitting layer EML, and an electron functional layer ETL between the light emitting layer EML and the common electrode CE.

The hole functional layer HIL may include at least one of a hole injection layer and/or a hole transport layer. For example, the hole functional layer HIL may include a hole transport layer, or may include a hole transport layer and a hole injection layer. The hole transport layer may facilitate the transport of holes, and may include a hole transport material. For example, the hole transport material may include, but is not limited to, carbazole derivatives, such as N-phenylcarbazole and polyvinylcarbazole, fluorene derivatives, triphenylamine derivatives, such as TPD(N,N′-bis(3-methylphenyl)-N,N′-diphenyl-[1,1-biphenyl]-4,4′-diamine) and TCTA(4,4′,4″-tris(N-carbazolyl)triphenylamine), NPB(N,N′-di(1-naphthyl)-N,N′-diphenylbenzidine), TAPC(4,4′-Cyclohexylidene bis[N,N-bis(4-methylphenyl)benzenamine]), and/or the like.

The electronic functional layer ETL may include at least one of an electron transport layer and/or an electron injection layer. The electron functional layer ETL is an element arranged on at least one emissive layer, and may be an optional element. For example, the emission stack LES may or may not include the electron functional layer ETL. The electron transport layer may facilitate the transport of electrons, and may include an electron transport material. The electron transport material may include, but is not limited to, an electron transparent material, such as Alq3(Tris(8-hydroxyquinolinato)aluminum), TPBi(1,3,5-Tri(1-phenyl-1H-benzo[d]imidazol-2-yl)phenyl), BCP(2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate), ADN(9,10-di(naphthalene-2-yl)anthracene), and/or a suitable mixture thereof.

According to an embodiment of the present disclosure, the light-emitting elements EMD may further include an electron blocking layer disposed between the hole functional layer HIL and the light emitting layer EML. The electron blocking layer may include a hole transport material and a metal or metal compound in order to block electrons generated in the light emitting layer EML from flowing to the hole functional layer HIL. According to an embodiment of the present disclosure, the hole transport layer and the electron blocking layer may be made up of a single layer in which the materials are mixed together.

The common electrode CE may be located on the emission stack LES. According to an embodiment of the present disclosure, the common electrode CE may be a translucent thin-film electrode including a metal. For example, the common electrode CE may include silver (Ag), magnesium (Mg), copper (Cu), aluminum (Al), lithium (Li), calcium (Ca), ytterbium (Yb), platinum (Pt), palladium (Pd), gold (Au), nickel (Ni), neodymium (Nd), iridium (Ir), chromium (Cr), molybdenum (Mo), titanium (Ti), or suitable compounds or mixtures thereof (e.g., a mixture of silver (Ag) and magnesium (Mg)), and may have translucent properties as it has a thickness of approximately tens to hundreds of angstroms. For example, the common electrode CE may be a translucent thin-film electrode having a light transmittance in the range of approximately 40% to 60%, but the light transmittance of the common electrode CE is not limited thereto.

A capping layer CPL may be located on the common electrode CE. The capping layer CPL may be included in the light-emitting element layer 300. The capping layer CPL may protect the light-emitting elements EMD from moisture permeating into the underlying light-emitting elements EMD or from foreign substances.

According to an embodiment of the present disclosure, the capping layer CPL may include at least one inorganic layer. For example, the capping layer CPL may include at least one of silicon oxide (SiOx), silicon nitride (SiNx), and/or silicon oxynitride (SiOxNy) as the inorganic layer. As another example, the capping layer CPL may include a plurality of inorganic layers. For example, the capping layer CPL may be made up of double-layers in which two of the above-described inorganic layers are stacked, or multi-layers in which the layers are alternately stacked.

The thin-film encapsulation layer TFEL may be placed on the light-emitting element layer 300. The thin-film encapsulation layer TFEL may be commonly located in the emission areas LA and the non-emission area NLA.

According to an embodiment of the present disclosure, the thin-film encapsulation layer TFEL may include a first encapsulation layer TFE1, a second encapsulation layer TFE2, and a third encapsulation layer TFE3 sequentially stacked on the capping layer CPL. In some embodiments, each of the first encapsulation layer TFE1 and the third encapsulation layer TFE3 may be an inorganic film made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, lithium fluoride, and/or the like. According to some embodiments, the second encapsulation layer TFE2 may be an organic film made of an acrylic resin, a methacrylic resin, a polyisoprene, a vinyl resin, an epoxy resin, a urethane resin, a cellulose resin, a perylene resin, and/or the like. The structure and material of the thin-film encapsulation layer TFEL may be variously modified as needed or desired.

Incidentally, some of the light generated in the light-emitting elements EMD may directly transmit through the common electrode CE to travel toward the front side of the display device 10. Some others of the light may be reflected by the reflective layer of the pixel electrode PE, and may transmit through the common electrode CE to travel toward the front side of the display device 10. For example, in FIG. 8, a portion of the first light L1 generated in at least one emissive layer included in the emission stack LES may directly transmit through the common electrode CE, while another portion of the light (e.g., the second light L2) may transmit through the common electrode CE after being reflected off the reflective layer of the pixel electrode PE.

Each of the light-emitting elements EMD may have a micro-cavity (e.g., a thin film resonance) structure. For example, depending on the position of at least one emissive layer included in the emission stack LES, and a distance between the pixel electrode PE and the common electrode CE, light of a desired wavelength range included in the first light L1 (e.g., red light, green light, and/or blue light) may be amplified by a constructive interference. For example, as indicated by the dotted arrow in FIG. 8, light of a desired wavelength range included in the second light L2 generated in at least one emissive layer included in the emission stack LES may transmit through the common electrode CE after its intensity has been amplified by the micro-cavity effect that occurs inside the emission stack LES.

Referring to FIG. 9, according to an embodiment of the present disclosure, the first light-emitting element EMD1, the second light-emitting element EMD2, and the third light-emitting element EMD3 may have different distances from each other between their respective pixel electrodes PE and the common electrode CE. Depending on the wavelength of light to be output from the emission area LA1, LA2, and LA3 of each pixel PX and the corresponding resonance distance, resonance order, and/or the like, the distance between the pixel electrode PE and the common electrode CE may be adjusted differently for each pixel PX, so that the micro-resonance effect for the light may be increased and/or optimized. For example, by differently adjusting thicknesses of the first light emitting layer EML1, the second light emitting layer EML2, and the third light emitting layer EML3 from each other, the distances between the pixel electrodes PE and the common electrode CE of the first light-emitting element EMD1, the second light-emitting element EMD2, and the third light-emitting element EMD3 may be adjusted differently from each other. For example, each of the light emitting layers EML1, EML2, and EML3 may have a suitable thickness corresponding to a compensation distance necessary or desired to adjust the distance between the pixel electrodes PE and the common electrode CE according to an nth resonance distance of light to be output from their respective emission areas LA, where n is a natural number.

According to an embodiment of the present disclosure, the distance between the pixel electrode PE and the common electrode CE in each of the emission areas LA may correspond to the resonance distance of light output through the emission area LA. For example, a first distance d1 between the pixel electrode PE and the common electrode CE in the first emission area LA1 may be equal to or substantially equal to the resonance distance of light of the first color output through the first emission area LA1 (e.g., the n^{th} resonance distance of the first color light). A second distance d2 between the pixel electrode PE and the common electrode CE in the second emission area LA2 may be equal to or substantially equal to the resonance distance of light of the second color output through the second emission area LA2. A third distance d3 between the pixel electrode PE and the common electrode CE in the third emission area LA3 may correspond to the resonance distance of light of the third color output through the third emission area LA3.

According to an embodiment of the present disclosure, at least one of the first light-emitting element EMD1, the second light-emitting element EMD2, and/or the third light-emitting element EMD3 may include an emission pattern AML (also referred to as an optical assist layer) locally located between the light emitting layer EML and the pixel electrode PE. For example, the second light-emitting element EMD2 may include the emission pattern AML between the hole functional layer HIL and the second light emitting layer EML2.

The emission pattern AML may be located in the second emission area LA2. For example, the emission pattern AML may overlap with the second pixel electrode PE2 and the second light emitting layer EML2 in the thickness direction (e.g., the third direction DR3). The emission pattern AML may emit light of the same color as that of the second light emitting layer EML2. For example, the emission pattern AML may be a green emissive layer, and may include a fluorescent material containing Alq3(tris(8-hydroxyquinolino)aluminum). The dopant material contained in the green emissive layer may be, for example, a metal complex such as Ir(ppy)3(fac-tris(2-phenylpyridine)iridium), or an organometallic complex.

The height of the common electrode CE arranged on the emission pattern AML may be changed by the emission pattern AML. The second emission area LA2 may include a first region Gd in which the second light emitting layer EML2 and the emission pattern AML do not overlap with each other, and a second area Go in which the second light emitting layer EML2 and the emission pattern AML overlap with each other. The height of the second light emitting layer EML2 in the second region Go may be greater than the height of the second light emitting layer EML2 in the first region Gd by the thickness (e.g., the height) of the emission pattern AML. Accordingly, the height of the common electrode CE in the second region Go where the emission pattern AML is arranged may be increased in the second emission area LA2. When the height of the common electrode CE is increased, the distance between the pixel electrode PE and the common electrode CE may be increased. Accordingly, an optical length and a reflection distance between the pixel electrode PE and the common electrode CE may be increased.

According to an embodiment of the present disclosure, depending on the wavelength of light to be output from the second pixel PX2 and the corresponding resonance distance, resonance order, and/or the like, the distance may be adjusted to have different optical lengths and reflection distances in the second emission area LA2 of the second pixel PX2, so that the micro-cavity effect for the light may be increased and/or optimized. For example, the distance between the pixel electrode PE and the common electrode CE in the second region Go may be set and/or adjusted using the emission pattern AML, so that the first region Gd and the second region Go of the second emission area LA2 have different optical lengths and reflection distances from each other.

According to an embodiment of the present disclosure, the distance d2 between the pixel electrode PE and the common electrode CE in the first region Gd of the second emission area LA2 may be smaller than the distance d4 between the pixel electrode PE and the common electrode CE in the second region Go. In other words, the distance d4 between the pixel electrode PE and the common electrode CE in the second region Go of the second emission area LA2 may be greater than the distance d2 between the pixel electrode PE and the common electrode CE in the first region Gd. For example, the distance d4 between the pixel electrode PE and the common electrode CE in the second region Go may be greater than the distance d2 between the pixel electrode PE and the common electrode CE in the first region Gd by the thickness of the emission pattern AML.

According to an embodiment of the present disclosure, by employing the emission pattern AML, the first region Gd and the second region Go may have different thicknesses from each other to form different resonance distances from each other, so that luminance and color differences of the display device 10 may be improved. For example, the visual quality may be improved by improving the luminance and color differences on the sides relative to the front.

Referring to FIG. 10, according to an embodiment of the present disclosure, the second emission area LA2 may be divided by a line extended in the second direction DR2. For example, the first region Gd may be adjacent to the first emission area LA1, and the second region Go may be adjacent to the third emission area LA3. However, the present disclosure is not limited thereto. The first region Gd may be adjacent to the third emission area LA3, and the second region Go may be adjacent to the first emission area LA1.

According to another embodiment of the present disclosure, the second emission area LA2 may be divided by a line extended in the first direction DR1. For example, the first region Gd may form the upper side of the second emission area LA2, while the second region Go may form the lower side of the second emission area LA2. However, the present disclosure is not limited thereto. The first region Gd may form the lower side of the second emission area LA2, while the second region Go may form the upper side of the second emission area LA2.

According to another embodiment, the emission pattern AML may be completely covered by the second light emitting layer EML2, such that the second region Go may be completely surrounded (e.g., around a periphery thereof) by the first region Gd. In addition, the shape of the emission pattern AML or the second region Go when viewed from the top (e.g., in a plan view) may be different from the shape of the second emission area LA2 when viewed from the top (e.g., in a plan view). For example, the shape of the emission pattern AML or the second region Go when viewed from the top (e.g., in a plan view) may be circular or polygonal.

According to an embodiment of the present disclosure, the area occupied by the first region Gd in the second emission area LA2 may be 40% to 70% of the entire second emission area LA2. In other words, the area occupied by the second region Go in the second emission area LA2 may be 30% to 60% of the entire second emission area LA2. The area of the second emission area LA2 may be equal to or substantially equal to the sum of the areas of the first region Gd and the second region Go.

According to an embodiment of the present disclosure, if (e.g., when) the area occupied by the first region Gd is equal to or greater than 40% relative to the entire second emission area LA2, and the area occupied by the second region Go is equal to or less than 60% relative to the entire second emission area LA2, the luminance at a side viewing angle of 60 degrees relative to the front and luminance ratio differences versus a viewing angle may be improved. In addition, if (e.g., when) the area occupied by the first region Gd is equal to or less than 70% relative to the entire second emission area LA2, and the area occupied by the second region Go is equal to or greater than 30% relative to the entire second emission area LA2, it may be possible to prevent or substantially prevent difficulties in controlling a current efficiency and viewing angle characteristics of the second light-emitting element EMD2.

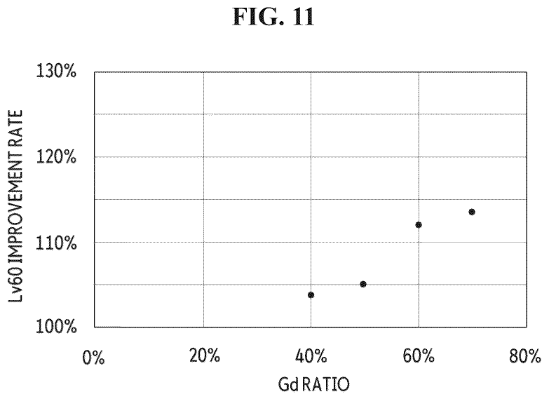

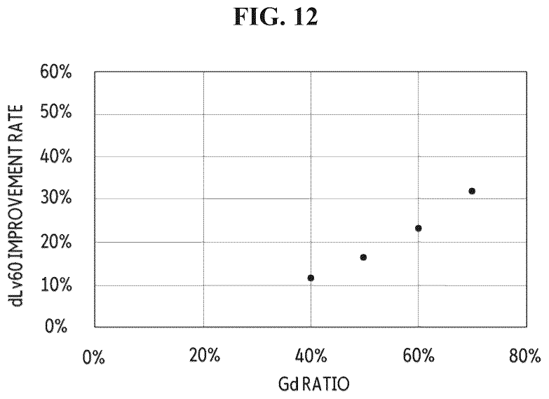

FIG. 11 is a graph showing a luminance improvement rate at a 60-degree viewing angle relative to a front versus a ratio of an area of a first region to a second emission area. FIG. 12 is a graph showing differences in a luminance improvement rate at a 60-degree viewing angle relative to a front versus a ratio of an area of a first region to a second emission area.

Referring to FIG. 11 and FIG. 12, as the ratio of the area of the first region Gd to the second emission area LA2 increases from 40% to 70%, the luminance improvement rate at the side viewing angle of 60 degrees relative to the front increases, and the differences in the luminance improvement rate also increase.

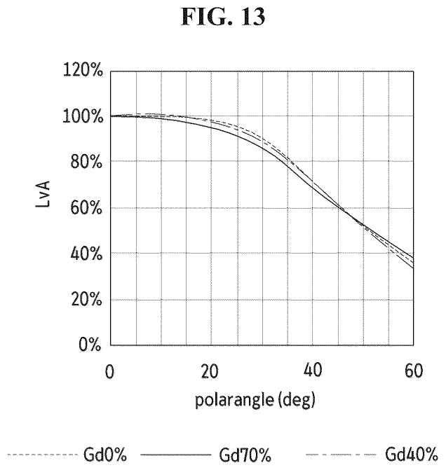

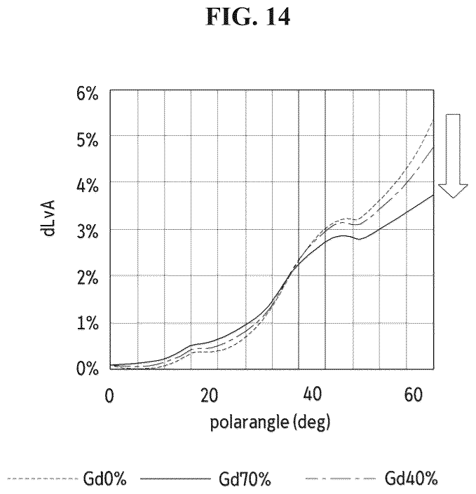

FIG. 13 is a graph showing a luminance ratio versus a viewing angle. FIG. 14 is a graph showing differences in a luminance ratio versus a viewing angle. FIGS. 13 and 14 show the luminance ratio and the differences in the luminance ratio versus a viewing angle when the ratio of the area of the first region Gd to the second emission area LA2 is 0%, 40%, and 70%. A polar angle of the horizontal axis refers to an angle at which the display device 10 is viewed from a side, with zero degree when it is viewed from the front.

Referring to FIG. 13, when the ratio of the area of the first region Gd to the second emission area LA2 is 0%, 40%, and 70%, the luminance ratios versus the viewing angle are almost equal (e.g., are similar) to each other.

Referring to FIG. 14, as the ratio of the area of the first region Gd to the second emission area LA2 is increased from 0%, 40%, and 70%, the differences in the luminance ratio at the viewing angle of approximately 60 degrees are reduced.

As shown in FIGS. 13 and 14, as the ratio of the area of the first region Gd to the second emission area LA2 increases, differences in the luminance ratio at the side viewing angle relative to the front may be reduced.

As described above, by forming the first region Gd and the second region Go having different resonance distances from each other in the second emission area LA2 using the emission pattern AML, the luminance differences and the color differences at side viewing angles relative to the front of the display device 10 may be improved. As such, it may be possible to prevent or substantially prevent the visual quality of the display device 10 from deteriorating.

According to an embodiment of the present disclosure, the display device 10 may further include a polarizing plate on the thin-film encapsulation layer TFEL. According to another embodiment of the present disclosure, the display device 10 may further include a color filter layer on the thin-film encapsulation layer TFEL. For example, the color filter layer may include a first color filter that transmits blue light, a second color filter that transmits green light, and a third color filter that transmits red light. The first color filter may be in line with the first emission area LA1, the second color filter may be in line with the second emission area LA2, and the third color filter may be in line with the third emission area LA3.

Hereinafter, some other embodiments of the present disclosure may be described in more detail. The same or similar elements are denoted by the same or similar reference numerals, and thus, redundant description thereof may not be repeated, or may be briefly described, and the differences from those described above may be mainly described hereinafter.

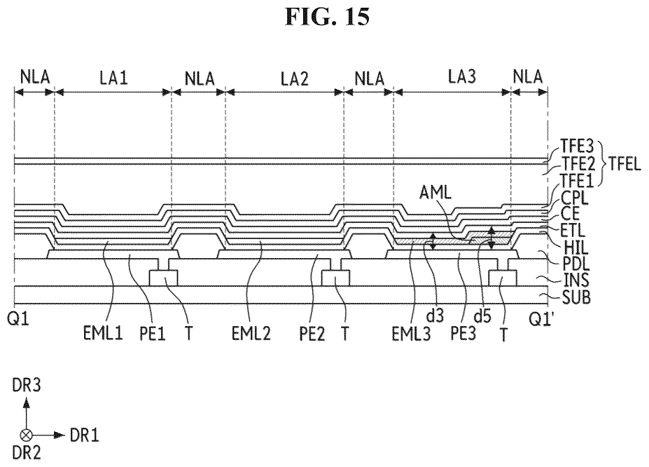

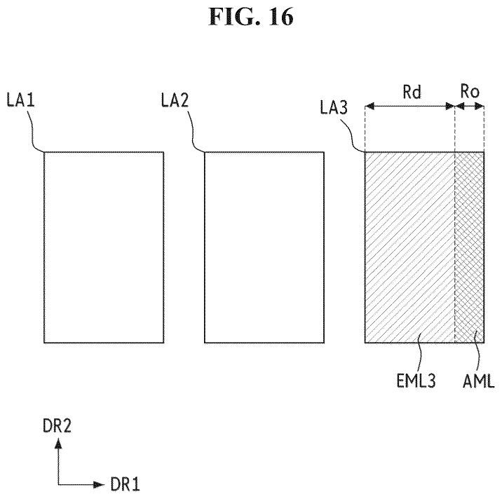

FIG. 15 is a cross-sectional view showing emission areas of a display device according to an embodiment of the present disclosure. FIG. 16 is a plan view showing emission areas of a display device according to an embodiment of the present disclosure.

The embodiment illustrated in FIGS. 15 and 16 may be different from the embodiments described above, in that an emission pattern AML may be located in a third emission area LA3.

According to an embodiment of the present disclosure, the emission pattern AML may be in line with the third emission area LA3. For example, the emission pattern AML may overlap with a third pixel electrode PE3 and a third light emitting layer EML3 in the thickness direction (e.g., the third direction DR3). The emission pattern AML may emit light of the same color as that of the third light emitting layer EML3. For example, the emission pattern AML may be a red emissive layer that emits red light, and may include a fluorescent material including PBD: Eu(DBM)3(Phen) (tris(dibenzoylmethanato)phenanthoroline europium) or perylene. The dopant material contained in the red emissive layer may be, for example, metal complexes, such as PIQIr(acac)(bis(1-phenylisoquinoline)acetylacetonate iridium), PQIr(acac)(bis(1-phenylquinoline)acetylacetonate iridium), and/or PQIr(tris(1-phenylquinoline)iridium) and PtOEP(octaethylporphyrin platinum, or an organometallic complex.

The height of the common electrode CE arranged on the emission pattern AML may be changed by the emission pattern AML. The third emission area LA3 may include a first region Rd in which the third light emitting layer EML3 and the emission pattern AML do not overlap with each other, and a second area Ro in which the third light emitting layer EML3 and the emission pattern AML overlap with each other. The height of the third light emitting layer EML3 in the second region Ro may be greater than the height of the third light emitting layer EML3 in the first region Rd by the thickness (e.g., the height) of the emission pattern AML. Accordingly, the height of the common electrode CE in the second region Ro where the emission pattern AML is arranged may be increased in the third emission area LA3. When the height of the common electrode CE is increased, the distance between the pixel electrode PE and the common electrode CE may be increased. Accordingly, the optical length and the reflection distance between the pixel electrode PE and the common electrode CE may be increased.

According to an embodiment of the present disclosure, depending on the wavelength of light to be output from the third pixel PX3 and the corresponding resonance distance, resonance order, and/or the like, the distance may be adjusted to have different optical lengths and reflection distances in the third emission area LA3 of the third pixel PX3, so that the micro-cavity effect for the light is increased and/or optimized. For example, the distance between the pixel electrode PE and the common electrode CE in the second region Ro may be set and/or adjusted using the emission pattern AML, so that the first region Rd and the second region Ro of the third emission area LA3 have different optical lengths and reflection distances from each other.

According to an embodiment of the present disclosure, the distance d3 between the pixel electrode PE and the common electrode CE in the first region Rd of the third emission area LA3 may be smaller than the distance d5 between the pixel electrode PE and the common electrode CE in the second region Ro. In other words, the distance d5 between the pixel electrode PE and the common electrode CE in the second region Ro of the third emission area LA3 may be greater than the distance d3 between the pixel electrode PE and the common electrode CE in the first region Rd. For example, the distance d5 between the pixel electrode PE and the common electrode CE in the second region Ro may be greater than the distance d3 between the pixel electrode PE and the common electrode CE in the first region Rd by the thickness of the emission pattern AML.

According to an embodiment of the present disclosure, different resonance distances may be formed by employing the emission pattern AML in the third emission area LA3 to make different thicknesses between the first region Rd and the second region Ro, so that luminance and color differences of the display device 10 may be improved. For example, a visual quality may be improved by improving the luminance and color differences on the sides relative to the front.

Referring to FIG. 16, according to an embodiment of the present disclosure, the third emission area LA3 may be divided by a line extended in the second direction DR2. For example, the first region Rd may be adjacent to the second emission area LA2, and the second region Ro may be distant (e.g., may be spaced apart) from the second emission area LA3. However, the present disclosure is not limited thereto. The first region Rd may be distant (e.g., may be spaced apart) from the second emission area LA2, while the second region Ro may be adjacent to the second emission area LA2.

According to another embodiment of the present disclosure, the third emission area LA3 may be divided by a line extended in the first direction DR1. For example, the first region Rd may form the upper side of the third emission area LA3, while the second region Ro may form the lower side of the third emission area LA3. However, the present disclosure is not limited thereto. The first region Rd may form the lower side of the third emission area LA3, while the second region Ro may form the upper side of the third emission area LA3.

According to another embodiment, the emission pattern AML may be completely covered by the third light emitting layer EML3, such that the second region Ro may be completely surrounded (e.g., around a periphery thereof) by the first region Rd. In addition, the shape of the emission pattern AML or the second region Ro when viewed from the top (e.g., in a plan view) may be different from the shape of the third emission area LA3 when viewed from the top (e.g., in a plan view). For example, the shape of the emission pattern AML or the second region Ro when viewed from the top (e.g., in a plan view) may be circular or polygonal.

According to an embodiment of the present disclosure, the area occupied by the first region Rd in the third emission area LA3 may be 20% to 40% of the entire third emission area LA3. In other words, the area occupied by the second region Ro in the third emission area LA3 may be 60% to 80% of the entire third emission area LA3. The area of the third emission area LA3 may be equal to or substantially equal to the sum of the areas of the first region Rd and the second region Ro.

According to an embodiment of the present disclosure, if (e.g., when) the area occupied by the first region Rd is equal to or greater than 20% relative to the entire third emission area LA3, and the area occupied by the second region Ro is equal to or less than 80% relative to the entire third emission area LA3, the luminance at the side viewing angle of 60 degrees relative to the front and differences in the luminance ratio according to the viewing angle may be improved. In addition, if (e.g., when) the area occupied by the first region Rd is equal to or less than 40% relative to the entire third emission area LA3, and the area occupied by the second region Ro is equal to or greater than 60% relative to the entire third emission area LA3, it may be possible to prevent or substantially prevent difficulties in controlling the current efficiency and viewing angle characteristics of the third light-emitting element EMD3.

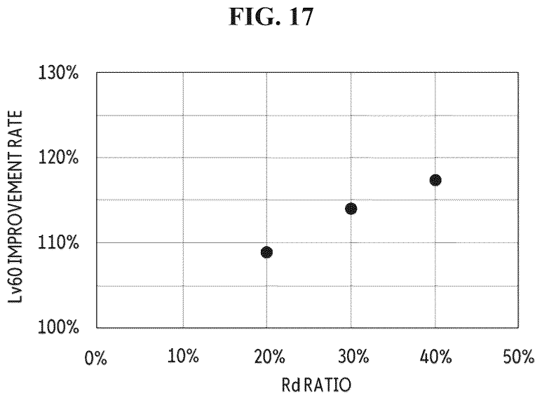

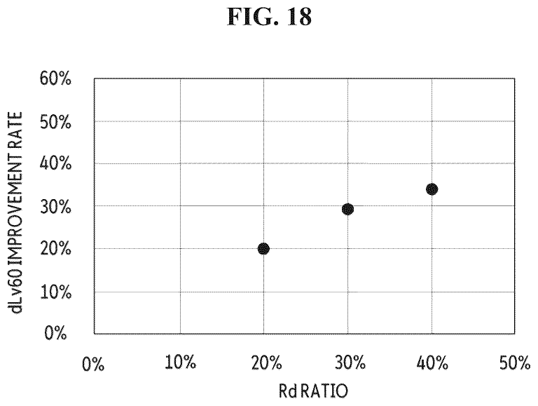

FIG. 17 is a graph showing a luminance improvement rate at a 60-degree viewing angle relative to a front versus a ratio of an area of a first region to a third emission area. FIG. 18 is a graph showing differences in a luminance improvement rate at a 60-degree viewing angle relative to a front versus a ratio of an area of a first region to a third emission area.

Referring to FIG. 17 and FIG. 18, as the ratio of the area of the first region Rd to the third emission area LA3 increases from 20% to 40%, the luminance improvement rate at the side viewing angle of 60 degrees relative to the front increases, and the differences in the luminance improvement rate also increase.

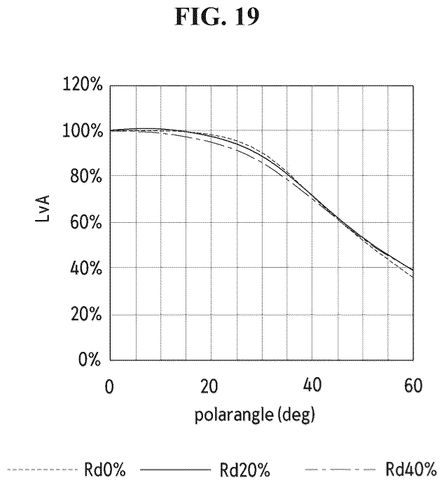

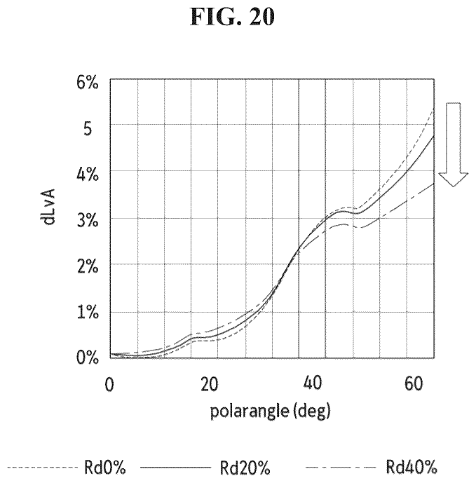

FIG. 19 is a graph showing a luminance ratio versus a viewing angle. FIG. 20 is a graph showing differences in a luminance ratio versus a viewing angle. FIGS. 19 and 20 show a luminance ratio and differences in a luminance ratio versus a viewing angle when the ratio of the area of the first region Rd to the third emission area LA3 is 0%, 20%, and 40%.

Referring to FIG. 19, when the ratio of the area of the first region Rd to the third emission area LA3 is 0%, 20%, and 40%, the luminance ratios according to the viewing angle are almost equal (e.g., are similar) to each other.

Referring to FIG. 20, as the ratio of the area of the first region Rd to the third emission area LA3 is increased from 0%, 20%, and 40%, differences in the luminance ratio at the viewing angle of approximately 60 degrees are reduced.

As shown in FIGS. 19 and 20, as the ratio of the area of the first region Rd to the third emission area LA3 increases, differences in the luminance ratio of the side viewing angle relative to the front may be reduced.

As described above, by forming the first region Rd and the second region Ro having different resonance distances from each other in the third emission area LA3 using the emission pattern AML, the luminance differences and the color differences at side viewing angles relative to the front of the display device 10 may be improved. As such, it may be possible to prevent or substantially prevent a visual quality of the display device 10 from deteriorating.

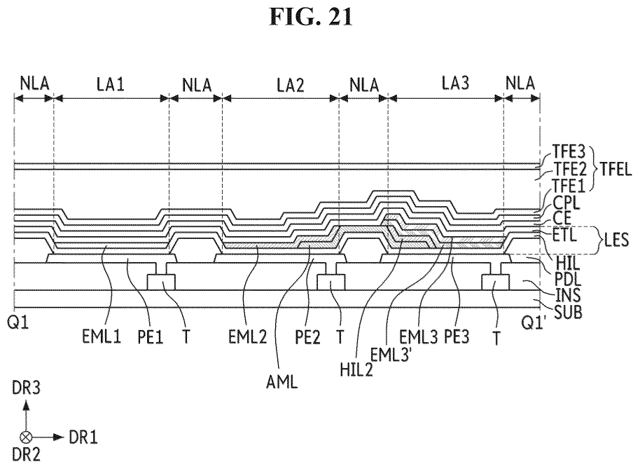

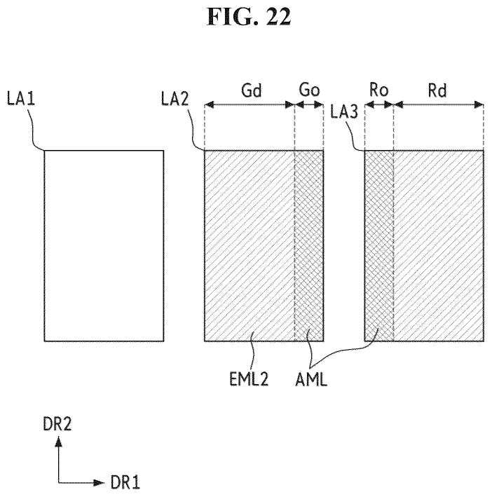

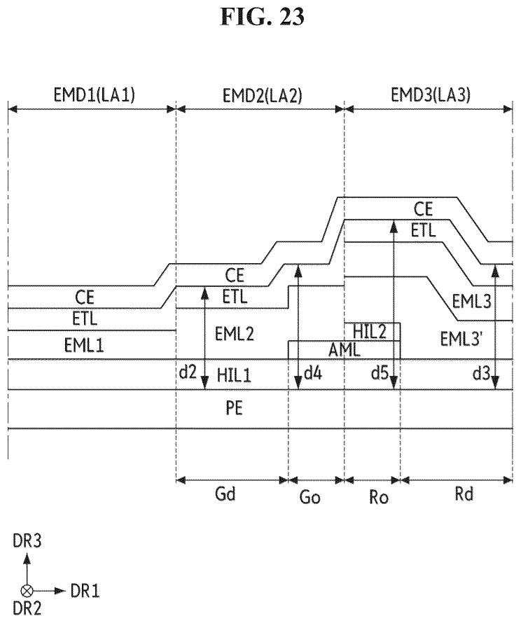

FIG. 21 is a cross-sectional view showing emission areas of a display device according to an embodiment of the present disclosure. FIG. 22 is a cross-sectional view showing light-emitting elements of a display device according to an embodiment of the present disclosure. FIG. 23 is a plan view showing emission areas of a display device according to an embodiment of the present disclosure.

The embodiment of FIGS. 21 to 23 may be different from the embodiments described above, in that an emission pattern AML may be arranged across a second emission area LA2 and a third emission area LA3, and thus, a first region Gd and a second region Go may be formed in the second emission area LA2, and a third region Rd and a fourth region Ro may be formed in the third emission area LA3.

According to an embodiment of the present disclosure, a first light-emitting element EMD1 located in a first emission area LA1 may include a first pixel electrode PE1, a first hole functional layer HIL1, a first light emitting layer EML1, an electron functional layer ETL, and a common electrode CE.

According to an embodiment of the present disclosure, a second light-emitting element EMD2 located in the second emission area LA2 may include a second pixel electrode PE2, the first hole functional layer HIL1, the emission pattern AML, a second light emitting layer EML2, an electron functional layer ETL, and the common electrode CE. The second emission area LA2 may include the first region Gd in which the second light emitting layer EML2 and the emission pattern AML do not overlap with each other, and the second region Go in which the second light emitting layer EML2 and the emission pattern AML overlap with each other.

According to an embodiment of the present disclosure, a third light-emitting element EMD3 located in the third emission area LA3 may include a third pixel electrode PE3, the first hole functional layer HIL1, the emission pattern AML, a second hole functional layer HIL2, an auxiliary light emitting layer EML3′, a third light emitting layer EML3, the electron functional layer ETL, and the common electrode CE. The third emission area LA3 may include the third region Rd in which the third light emitting layer EML3 and the emission pattern AML do not overlap with each other, and the fourth region Ro in which the third light emitting layer EML3 and the emission pattern AML overlap with each other. In addition, in the fourth region Ro, the emission pattern AML and the second hole functional layer HIL2 may overlap with each other.

The emission pattern AML may be extended from the second emission area LA2 to the third emission area LA3. For example, the emission pattern AML may be extended continuously from the second emission area LA2 to the third emission area LA3 beyond the pixel-defining layer PDL between the second emission area LA2 and the third emission area LA3 on the first hole functional layer HIL1. The emission pattern AML may be a common layer that is formed commonly in the second emission area LA2 as well as the third emission area LA3. The emission pattern AML may overlap with not only with the second emission area LA2 and the third emission area LA3, but may also overlap with the non-emission area NLA between the second emission area LA2 and the third emission area LA3.

The emission pattern AML may emit light of the same color as that of the second light emitting layer EML2, as described above. For example, the emission pattern AML may be a green emissive layer, and may include a fluorescent material containing Alq3(tris(8-hydroxyquinolino)aluminum). The dopant material contained in the green emissive layer may be, for example, a metal complex such as Ir(ppy)3(fac-tris(2-phenylpyridine)iridium), or an organometallic complex.

According to an embodiment of the present disclosure, the second hole functional layer HIL2 may be located on the emission pattern AML. The second hole functional layer HIL2 may facilitate the movement of holes from the emission pattern AML to the auxiliary light emitting layer EML3′. The second hole functional layer HIL2 may cover at least a portion of the emission pattern AML, and may cover one side surface.

The first hole functional layer HIL1 and the second hole functional layer HIL2 may be the same or substantially the same as the hole functional layer HIL of the above-described embodiments. For example, each of the first hole functional layer HIL1 and the second hole functional layer HIL2 may include at least one of a hole injection layer and/or a hole transport layer. For example, each of the first hole functional layer HIL1 and the second hole functional layer HIL2 may include the hole transport layer, or the hole transport layer and the hole injection layer.

The hole transport layer may facilitate the transport of holes, and may include a hole transport material. For example, the hole transport material may include, but is not limited to, carbazole derivatives, such as N-phenylcarbazole and polyvinylcarbazole, fluorene derivatives, triphenylamine derivatives, such as TPD(N,N′-bis(3-methylphenyl)-N,N′-diphenyl-[1,1-biphenyl]-4,4′-diamine) and TCTA(4,4′,4″-tris(N-carbazolyl)triphenylamine), NPB(N,N′-di(1-naphthyl)-N,N′-diphenylbenzidine), TAPC(4,4′-Cyclohexylidene bis[N,N-bis(4-methylphenyl)benzenamine]), and/or the like.

The auxiliary light emitting layer EML3′ may be located on the emission pattern AML, the second hole functional layer HIL2, and the first hole functional layer HIL1. The auxiliary light emitting layer EML3′ may cover the second hole functional layer HIL2, and may cover at least a portion of the emission pattern AML.

The auxiliary light emitting layer EML3′ may emit light of the same color as that of the third light emitting layer EML3. For example, the auxiliary light emitting layer EML3′ may be a red emissive layer that emits red light, and may include a fluorescent material including PBD: Eu(DBM)3(Phen) (tris(dibenzoylmethanato)phenanthoroline europium) or perylene. The dopant material contained in the red emissive layer may be, for example, metal complexes, such as PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), and/or PtOEP(octaethylporphyrin platinum, or an organometallic complex.

The height of the common electrode CE arranged on the auxiliary light emitting layer EML3′ may be changed by the auxiliary light emitting layer EML3′. The height of the third light emitting layer EML3 of the third emission area LA3 may be increased by the thickness (e.g., the height) of the auxiliary light emitting layer EML3′. As a result, the height of the common electrode CE placed in the third emission area LA3 may be increased. When the height of the common electrode CE is increased, the distance between the third pixel electrode PE3 and the common electrode CE increases, so that the optical length and the reflection distance may be increased. In other words, depending on the wavelength of light to be output from the third pixel PX3 (e.g., the third emission area) and the corresponding resonance distance, resonance order, and/or the like, the micro-cavity effect for the light may be increased and/or optimized. For example, the distance between the third pixel electrode PE3 and the common electrode CE may be set and/or adjusted using the auxiliary light emitting layer EML3′ in the third emission area LA3 to achieve the optimal micro-cavity effect.

Incidentally, according to an embodiment of the present disclosure, the height of the common electrode CE arranged on the emission pattern AML may be changed by the emission pattern AML. The height of the second light emitting layer EML2 in the second region Go in the second emission area LA2 may be greater than the height of the second light emitting layer EML2 in the first region Gd by the thickness (e.g., the height) of the emission pattern AML. Accordingly, the height of the common electrode CE in the second region Go where the emission pattern AML is arranged may be increased in the second emission area LA2. When the height of the common electrode CE is increased, the distance between the pixel electrode PE and the common electrode CE may be increased. Accordingly, the optical length and reflection distance between the pixel electrode PE and the common electrode CE may be increased.

In addition, the height of the third light emitting layer EML3 in the fourth region Ro in the third emission area LA3 may be greater than the height of the third light emitting layer EML3 in the third region Rd by the thickness (e.g., the height) of the emission pattern AML. Accordingly, the height of the common electrode CE in the fourth region Ro where the emission pattern AML is arranged may be increased in the third emission area LA3.

According to an embodiment of the present disclosure, depending on the wavelength of light to be output from the second pixel PX2 and the third pixel PX3 and the corresponding resonance distance, resonance order, and/or the like, the distance may be adjusted to have different optical lengths and reflection distances in the second emission area LA2 of the second pixel PX and the third emission area LA3 of the third pixel PX3, so that the micro-cavity effect for the light may be increased and/or optimized. For example, the distance between the pixel electrode PE and the common electrode CE in the second region Go and the fourth region Ro may be set and/or adjusted using the emission pattern AML, so that the first region Gd and the second region Go of the second emission area LA2 have different optical lengths and reflection distances from each other, and the third region Rd and the fourth region Ro of the third emission area LA3 have different optical lengths and reflection distances from each other.

According to an embodiment of the present disclosure, the distance d2 between the pixel electrode PE and the common electrode CE in the first region Gd of the second emission area LA2 may be smaller than the distance d4 between the pixel electrode PE and the common electrode CE in the second region Go. In other words, the distance d4 between the pixel electrode PE and the common electrode CE in the second region Go of the second emission area LA2 may be greater than the distance d2 between the pixel electrode PE and the common electrode CE in the first region Gd. For example, the distance d4 between the pixel electrode PE and the common electrode CE in the second region Go may be greater than the distance d2 between the pixel electrode PE and the common electrode CE in the first region Gd by the thickness of the emission pattern AML.

In addition, the distance d3 between the pixel electrode PE and the common electrode CE in the third region Rd of the third emission area LA3 may be smaller than the distance d5 between the pixel electrode PE and the common electrode CE in the fourth region Ro. In other words, the distance d5 between the pixel electrode PE and the common electrode CE in the fourth region Ro of the third emission area LA3 may be greater than the distance d3 between the pixel electrode PE and the common electrode CE in the third region Rd. For example, the distance d5 between the pixel electrode PE and the common electrode CE in the fourth region Ro may be greater than the distance d3 between the pixel electrode PE and the common electrode CE in the third region Rd by the thickness of the emission pattern AML.

According to an embodiment of the present disclosure, the distance d3 between the pixel electrode PE and the common electrode CE in the third region Rd of the third emission area LA3 may be greater than the distance d2 between the pixel electrode PE and the common electrode CE in the first region Gd of the second emission area LA2 and the distance d4 between the pixel electrode PE and the common electrode CE in the second region Go. In addition, the distance d5 between the pixel electrode PE and the common electrode CE in the fourth region Ro may be greater than the distance d2 between the pixel electrode PE and the common electrode CE in the first region Gd of the second emission area LA2 and the distance d4 between the pixel electrode PE and the common electrode CE in the second region Go.

According to an embodiment of the present disclosure, by employing the emission pattern AML, the first region Gd and the second region Go of the second emission area LA2 may have different thicknesses from each other to form different resonance distances from each other, and the third region Rd and the fourth region Ro of the third emission area LA3 have different thicknesses from each other to form different resonance distances from each other, so that luminance and color differences of the display device 10 may be improved. For example, the visual quality may be improved by improving the luminance and color differences on the sides relative to the front. While green light and red light are sensitively perceived by the user, blue light hardly affects the user's visual perception. Accordingly, according to an embodiment of the present disclosure, the luminance and color differences of the display device 10 may be further improved by employing the emission pattern AML to the second emission area LA2 and the third emission area LA3 that emit green light and red light, respectively.

Referring to FIG. 22, according to an embodiment of the present disclosure, the second emission area LA2 and the third emission area LA3 may be divided by a line extended in the second direction DR2. For example, in the second emission area LA2, the first region Gd may be adjacent to the first emission area LA1, and the second region Go may be adjacent to the third emission area LA3. In the third emission area LA3, the third region Rd may be distant (e.g., may be spaced apart) from the second emission area LA2, and the fourth region Ro may be adjacent to the second emission area LA2. However, the present disclosure is not limited thereto. In the second emission area LA2, the first region Gd may be adjacent to the third emission area LA3, and the second region Go may be adjacent to the first emission area LA1. In the third emission area LA3, the third region Rd may be adjacent to the second emission area LA2, and the fourth region Ro may be distant (e.g., may be spaced apart) from the second emission area LA2.

According to another embodiment of the present disclosure, the second emission area LA2 and the third emission area LA3 may be divided by a line extended in the first direction DR1. For example, the first region Gd may form the upper side of the second emission area LA2, while the second region Go may form the lower side of the second emission area LA2. The third region Rd may form the upper side of the third emission area LA3, while the fourth region Ro may form the lower side of the third emission area LA3. However, the present disclosure is not limited thereto. The first region Gd may form the lower side of the second emission area LA2, the second region Go may form the upper side of the second emission area LA2, the third region Rd may form the lower side of the third emission area LA3, and the fourth region Ro may form the upper side of the third emission area LA3.

According to an embodiment of the present disclosure, the area occupied by the first region Gd in the second emission area LA2 may be 40% to 70% of the entire second emission area LA2, and the area occupied by the third region Rd in the third emission area LA3 may be 20% to 40% of the entire third emission area LA3. In other words, the area occupied by the second region Go in the second emission area LA2 may be 30% to 60% of the entire second emission area LA2, and the area occupied by the fourth region Ro in the third emission area LA3 may be 60% to 80% of the entire third emission area LA3. The area of the second emission area LA2 may be equal to or substantially equal to the sum of the areas of the first region Gd and the second region Go, and the area of the third emission area LA3 may be equal to or substantially equal to the sum of the areas of the third region Rd and the fourth region Ro.

According to an embodiment of the present disclosure, if (e.g., when) the area occupied by the first region Gd is equal to or greater than 40% relative to the entire second emission area LA2, and the area occupied by the third region Rd is equal to or greater than 20% relative to the entire third emission area LA3, the luminance at the side viewing angle of 60 degrees relative to the front and differences in the luminance ratio according to the viewing angle may be improved. In addition, if (e.g., when) the area occupied by the first region Gd is equal to or less than 70% relative to the entire second emission area LA2, and the area occupied by the third region Rd is equal to or less than 40% relative to the entire third emission area LA3, it may be possible to prevent or substantially prevent difficulties in controlling the current efficiency and the viewing angle characteristics of the second light-emitting element EMD2 and the third light-emitting element EMD3.

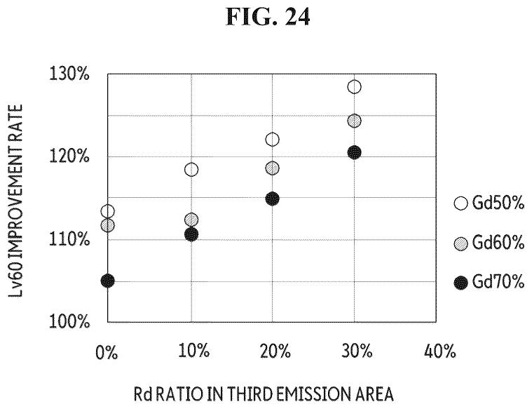

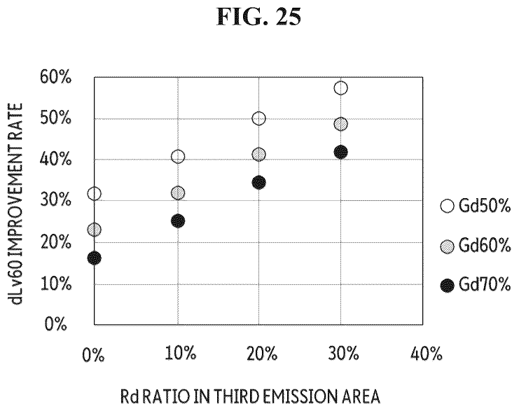

FIG. 24 is a graph showing a luminance improvement rate at a 60-degree viewing angle relative to a front versus a ratio of an area of a first region to a second emission area and a ratio of an area of a third region to a third emission area. FIG. 25 is a graph showing differences in a luminance improvement rate at a 60-degree viewing angle relative to a front versus a ratio of an area of a first region to a second emission area and a ratio of an area of a third region to a third emission area.

Referring to FIG. 24 and FIG. 25, as the ratio of the area of the third region Rd to the third emission area LA3 increases from 0% to 30%, the luminance improvement rate at the side viewing angle of 60 degrees relative to the front increases when the ratio of the area of the first region Gd of the second emission area LA2 is 50%, 60% and 70%, and the differences in the luminance improvement rate also increase.

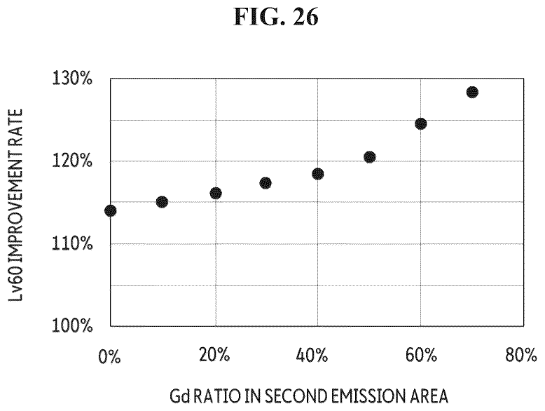

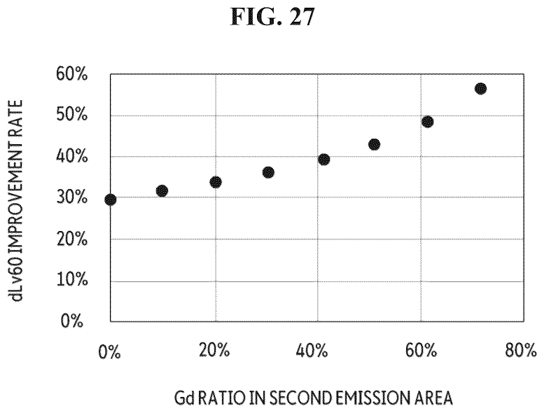

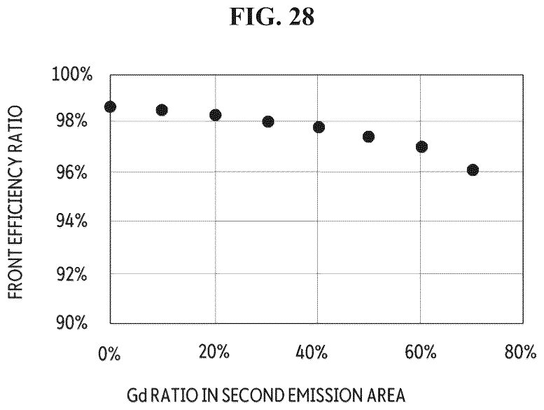

FIG. 26 is a graph showing a luminance improvement rate at a 60-degree viewing angle relative to a front versus a ratio of an area of a first region to a second emission area. FIG. 27 is a graph showing differences in a luminance improvement rate at a 60-degree viewing angle relative to a front versus a ratio of an area of a first region to a second emission area. FIG. 28 is a graph showing a front efficiency ratio versus a ratio of an area of a first region in a second emission area. In FIGS. 26, 27, and 28, the ratio of the area of the third region in the third emission area is fixed to 30%, and the ratio of the area of the first region is increased from 0% to 70%. In addition, the front efficiency ratio in FIG. 28 shows the ratio compared to a display device without an emission pattern.

Referring to FIG. 26 and FIG. 27, as the ratio of the area of the first region Gd in the second emission area LA2 increases from 0% to 70% while the ratio of the area of the third region Rd in the third emission area LA3 is fixed to 30%, the luminance improvement rate at the side viewing angle of 60 degrees relative to the front increases, and the differences in the luminance improvement rate also increase.

As shown in FIG. 28, the reduced front efficiency ratio may be maintained within 5% compared to the display device without an emission pattern.

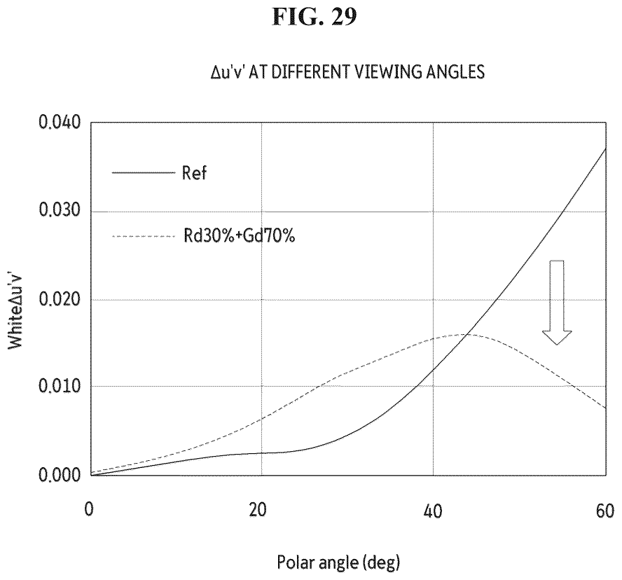

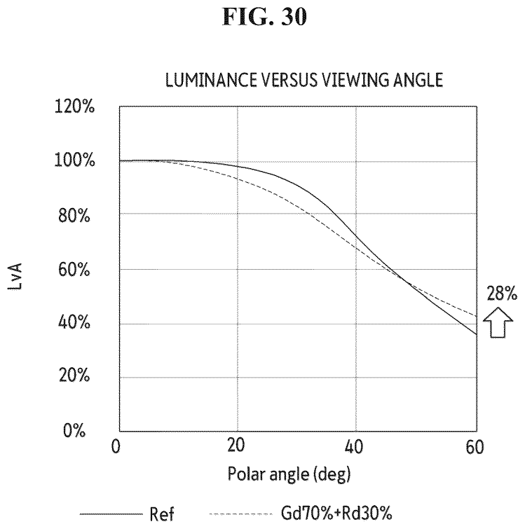

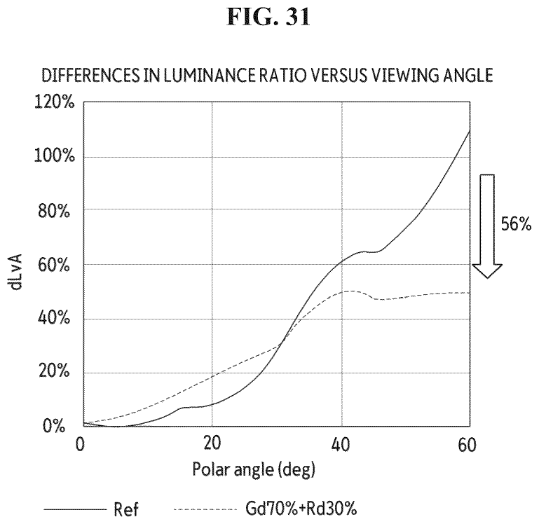

FIG. 29 is a graph showing differences in white color coordinates versus a viewing angle. FIG. 30 is a graph showing a luminance versus a viewing angle. FIG. 31 is a graph showing differences in a luminance ratio versus a viewing angle. In the graphs in FIGS. 29 to 31, a curve Ref denotes a display device without an emission pattern.

Referring to FIG. 29, if (e.g., when) the area of the first region Gd in the second emission area LA2 is 70% and the area of the third region Rd in the third emission area LA3 is 30% in a display device, differences in the white color coordinates at a side viewing angle greater than 45 degrees may be significantly reduced compared to those of the display device without an emission pattern.

Referring to FIG. 30, if (e.g., when) the area of the first region Gd in the second emission area LA2 is 70% and the area of the third region Rd in the third emission area LA3 is 30% in a display device, the luminance at the 60-degree side viewing angle may be increased by approximately 28% compared to that of the display device without an emission pattern.

Referring to FIG. 31, if (e.g., when) the area of the first region Gd in the second emission area LA2 is 70% and the area of the third region Rd in the third emission area LA3 is 30% in a display device, differences in the luminance ratio at the 60-degree side viewing angle may be reduced by approximately 56% compared to those of a display device without an emission pattern.

As described above, by using the emission pattern AML, the first region Gd and the second region Go having different resonance distances from each other in the second emission area LA2 may be formed, and the third region Rd and the fourth region Ro having different resonance distances from each other in the third emission area LA3 may be formed, so that the luminance differences and the color differences at side viewing angles relative to the front of the display device 10 may be improved. As such, it may be possible to prevent or substantially prevent the visual quality of the display device 10 from deteriorating.

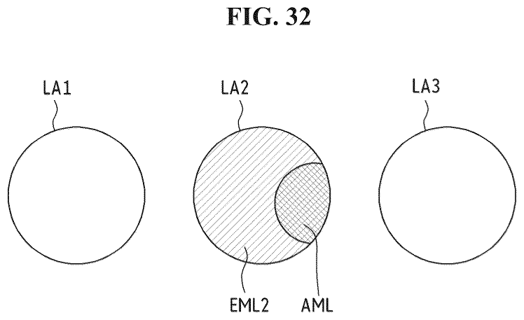

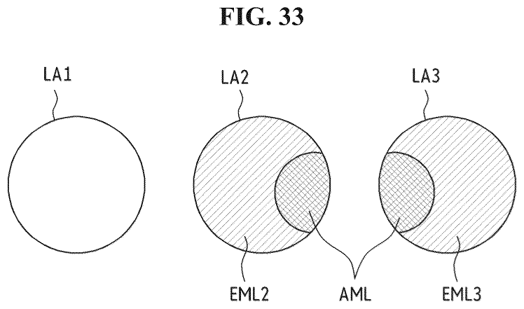

FIGS. 32 and 33 are plan views showing emission areas of a display device according to some embodiments.

The embodiments of FIGS. 32 and 33 may be different from the embodiments described above, in that the shape of each of the emission areas LA1, LA2, and LA3 may be circular when viewed from the top (e.g., in a plan view).

Referring to FIG. 32, an emission pattern AML may overlap with the second emission area LA2. The emission pattern AML may overlap with the second light emitting layer EML2, and may be located on one side in the second emission area LA2. Because the shape of the second emission area LA2 may be circular when viewed from the top (e.g., in a plan view), the emission pattern AML may also have a shape similar to that of a circle when viewed from the top (e.g., in a plan view). For example, the shape of the emission pattern AML when viewed from the top (e.g., in a plan view) may be generally elliptical with an arc on one side. However, the present disclosure is not limited thereto. The shape of the emission pattern AML may be circular, like that of the second emission area LA2.

Referring to FIG. 33, the emission pattern AML may overlap with the second emission area LA2 and the third emission area LA3. The emission pattern AML may overlap with the second light emitting layer EML2 and the third light emitting layer EML3, and may be located on one side in the second emission area LA2 and one side in the third emission area LA3. The emission pattern AML may also have a shape similar to that of a circle when viewed from the top (e.g., in a plan view). For example, the shape of the emission pattern AML when viewed from the top (e.g., in a plan view) may be generally elliptical with an arc on one side. However, the present disclosure is not limited thereto. The shape of the emission pattern AML may be circular, like that of the second emission area LA2 or the third emission area LA3, or a variety of suitable shapes may be applied.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate comprising a first emission area, a second emission area, and a third emission area; and
a first light-emitting element in the first emission area, a second light-emitting element in the second emission area, and a third light-emitting element in the third emission area, each of the first, second, and third light-emitting elements comprising a pixel electrode, a light emitting layer, and a common electrode on the substrate,
wherein at least one of the first light-emitting element, the second light-emitting element, or the third light-emitting element further comprises an emission pattern located between the pixel electrode and the light emitting layer, and
wherein at least one of the first emission area, the second emission area, or the third emission area in which the emission pattern is located comprises a first region where the light emitting layer and the emission pattern do not overlap with each other, and a second region where the light emitting layer and the emission pattern overlap with each other.

2. The display device of claim 1, wherein the second light-emitting element comprises the emission pattern, and an area occupied by the first region in the second emission area ranges from 40% to 70%.

3. The display device of claim 2, wherein an area occupied by the second region in the second emission area ranges from 30% to 60%.

4. The display device of claim 2, wherein the emission pattern comprises a material configured to emit light of a same color as that of the light emitting layer of the second light-emitting element overlapping with the emission pattern in a thickness direction.

5. The display device of claim 1, wherein the third light-emitting element comprises the emission pattern, and an area occupied by the first region in the third emission area ranges from 20% to 40%.

6. The display device of claim 5, wherein an area occupied by the second region in the third emission area ranges from 60% to 80%.

7. The display device of claim 5, wherein the emission pattern comprises a material configured to emit light of a same color as that of the light emitting layer of the third light-emitting element overlapping with the emission pattern in a thickness direction.

8. The display device of claim 1, wherein the second light-emitting element and the third light-emitting element comprise the emission pattern, and the emission pattern continuously extends across from the second light-emitting element to the third light-emitting element.

9. The display device of claim 8, further comprising:
a non-emission area located between the second emission area and the third emission area,
wherein the emission pattern overlaps with the non-emission area located between the second emission area and the third emission area, the second emission area, and the third emission area.

10. The display device of claim 8, wherein the second emission area comprises the first region where the emission pattern and the light emitting layer of the second light-emitting element do not overlap with each other, and the second region where the emission pattern and the light emitting layer of the second light-emitting element overlap with each other, and
wherein the third emission area comprises a third region where the emission pattern and the light emitting layer of the third light-emitting element do not overlap with each other, and a fourth region where the emission pattern and the light emitting layer of the third light-emitting element overlap with each other.

11. The display device of claim 10, wherein an area occupied by the first region in the second emission area ranges from 40% to 70%, and an area occupied by the third region in the third emission area ranges from 20% to 40%.

12. The display device of claim 1, wherein the first emission area is configured to output blue light, the second emission area is configured to output green light, and the third emission area is configured to output red light.

13. A display device comprising:
a substrate comprising a first emission area and a second emission area;
a first pixel electrode in the first emission area, and a second pixel electrode in the second emission area;
an emission pattern continuously extending across the first pixel electrode and the second pixel electrode;
a first light emitting layer overlapping with the first pixel electrode and the emission pattern, and a second light emitting layer overlapping with the second pixel electrode and the emission pattern; and
a common electrode on the first light emitting layer and the second light emitting layer,
wherein the first emission area comprises a first region where the first light emitting layer and the emission pattern do not overlap with each other, and a second region where the first light emitting layer and the emission pattern overlap with each other,
wherein the second emission area comprises a third region where the second light emitting layer and the emission pattern do not overlap with each other, and a fourth region where the second light emitting layer and the emission pattern overlap with each other, and
wherein the second region and the fourth region are adjacent to each other.

14. The display device of claim 13, wherein an area occupied by the first region in the first emission area ranges from 40% to 70%, and an area occupied by the third region in the second emission area ranges from 20% to 40%.

15. The display device of claim 13, wherein an area occupied by the second region in the first emission area ranges from 30% to 60%, and an area occupied by the fourth region in the second emission area ranges from 60% to 80%.

16. The display device of claim 13, further comprising:
a hole functional layer between the first pixel electrode and the emission pattern, and between the second pixel electrode and the emission pattern; and
an electron functional layer between the first light emitting layer and the common electrode, and between the second light emitting layer and the common electrode,
wherein the hole functional layer and the electron functional layer are common layers continuously extending across the first emission area and the second emission area.

17. The display device of claim 13, comprising:
a first hole functional layer on the second pixel electrode;
a second hole functional layer on the first hole functional layer; and
an auxiliary light emitting layer on the second hole functional layer and the first hole functional layer,
wherein the emission pattern is located between the first hole functional layer and the second hole functional layer, and
wherein the second light emitting layer is located on the auxiliary light emitting layer.

18. The display device of claim 13, wherein the substrate further comprises a third emission area,
wherein the display device further comprises:
a third pixel electrode in the third emission area;
a third light emitting layer on the third pixel electrode; and
the common electrode on the third light emitting layer, and
wherein the emission pattern does not overlap with the third emission area.

19. The display device of claim 18, wherein the first light emitting layer is configured to emit green light, the second light emitting layer is configured to emit red light, and the third light emitting layer is configured to emit blue light.

20. An electronic device comprising:
a display device configured to display images;
a processor configured to provide an image data signal to the display device;
a memory configured to store data information for an operation; and
a power circuit configured to generate power,
wherein the display device comprises:
a substrate comprising a first emission area, a second emission area, and a third emission area; and
a first light-emitting element in the first emission area, a second light-emitting element in the second emission area, and a third light-emitting element in the third emission area, each of the first, second, and third light-emitting elements comprising a pixel electrode, a light emitting layer, and a common electrode on the substrate,
wherein at least one of the first light-emitting element, the second light-emitting element, or the third light-emitting element further comprises an emission pattern located between the pixel electrode and the light emitting layer, and
wherein at least one of the first emission area, the second emission area, or the third emission area in which the emission pattern is located comprises a first region where the light emitting layer and the emission pattern do not overlap with each other, and a second region where the light emitting layer and the emission pattern overlap with each other.
